(19) United States
(12) Patent Application Publication
(10) Pub. No.: US 2015/0279793 A1
(43) Pub. Date: Oct. 1, 2015

(54) SEMICONDUCTOR STRUCTURE AND MANUFACTURING METHOD THEREOF

(71) Applicant: TAIWAN SEMICONDUCTOR MANUFACTURING COMPANY LTD., Hsinchu (TW)

(72) Inventors: HUNG-JUI KUO, HSINCHU CITY (TW); CHUNG-SHI LIU, HSINCHU CITY (TW)

(73) Assignee: TAIWAN SEMICONDUCTOR MANUFACTURING COMPANY LTD., Hsinchu (TW)

(21) Appl. No.: 14/227,336

(22) Filed: Mar. 27, 2014

(51) Int. Cl. H01L 23/00

(52) U.S. Cl. CPC H01L 24/13; H01L 24/11; H01L 2224/13147; H01L 2924/2064; H01L 2224/13017; H01L 2224/13023

(57) ABSTRACT

A semiconductor structure includes a substrate, a conductive interconnection exposed from the substrate, a passivation covering the substrate and a portion of the conductive interconnection, an under bump metallurgy (UBM) pad disposed over the passivation and contacted with an exposed portion of the conductive interconnection, and a conductor disposed over the UBM pad, wherein the conductor includes a top surface, a first sloped outer surface extended from the top surface and including a first gradient, and a second sloped outer surface extended from an end of the first sloped outer surface to the UBM pad and including a second gradient substantially smaller than the first gradient.

### BACKGROUND

Electronic equipment using semiconductor device are essential for many modern applications. With the advancement of electronic technology, electronic equipment is becoming increasingly smaller in size while having greater functionality and greater amounts of integrated circuitry. Thus, manufacturing of the electronic equipment includes more and more steps of assembly and involves various materials for producing the semiconductor device in the electronic equipment. Therefore, there is a continuous demand on improving a configuration of the electronic equipment, increasing a production efficiency and lowering an associated manufacturing cost on each electronic equipment.

The major trend in the electronic industry is to make the semiconductor device smaller and more multifunctional. The semiconductor device comprises numbers of components overlaying on each other and several electrical interconnection structures for electrically connecting the components between adjacent layers, such that the final size of the semiconductor device as well as the electronic equipment is minimized. However, as different layers and components include different kinds of materials with different thermal properties, the semiconductor device in such configuration would have delamination and bondability issues. The poor bondability between components would lead to delamination of components and yield loss of the semiconductor device. Furthermore, the components of the semiconductor device includes various metallic materials which are in limited quantity and thus in a high cost. The yield loss of the semiconductor would further exacerbate materials wastage and thus the manufacturing cost would increase.

Numerous manufacturing operations are implemented within such a small and high performance semiconductor device. Thus, manufacturing the semiconductor device in a miniaturized scale becomes more complicated. An increase in a complexity of manufacturing the semiconductor device may cause deficiencies such as poor reliability of the electrical interconnection, development of cracks within components and delamination of layers. Thus, there is a continuous need to improve a structure and a manufacturing method for of the semiconductor device in order to solve the above deficiencies.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view of a semiconductor structure with a conductor including sloped outer surfaces in accordance with some embodiments.

FIG. 1A is a schematic view of a semiconductor structure with a conductor including a protruded conductive base portion in accordance with some embodiments.

FIG. 2 is a schematic view of a semiconductor structure with a conductor including sloped outer surfaces in accordance with some embodiments.

FIG. 3 is a schematic view of a semiconductor structure with several conductors in accordance with some embodiments.

FIG. 4 is a schematic view of a semiconductor structure with a solder material in accordance with some embodiments.

FIG. 5 is a schematic view of a semiconductor structure with a first substrate boned with a second substrate in accordance with some embodiments.

FIG. 6 is a schematic view of a semiconductor structure with a conductor including a conductive top portion and a conductive base portion in accordance with some embodiments.

FIG. 7 is a flow diagram of a method of manufacturing a semiconductor structure in accordance with some embodiments.

FIG. 7A is a schematic view of a semiconductor structure with a substrate in accordance with some embodiments.

FIG. 7B is a schematic view of a semiconductor structure with a passivation in accordance with some embodiments.

FIG. 7C is a schematic view of a semiconductor structure with a recess in accordance with some embodiments.

FIG. 7D is a schematic view of a semiconductor structure with an UBM pad in accordance with some embodiments.

FIG. 7E is a schematic view of a semiconductor structure with a photoresist in accordance with some embodiments.

FIG. 7F is a schematic view of a semiconductor structure with an opening of a photoresist in accordance with some embodiments.

FIG. 7G is a schematic view of a semiconductor structure with a first opening and a second opening in accordance with some embodiments.

FIG. 7H is a schematic view of a semiconductor structure with an opening including a tapered sidewall in accordance with some embodiments.

FIG. 7I is a schematic view of a semiconductor structure with a conductor within an opening of a photoresist in accordance with some embodiments.

FIG. 7J is a schematic view of a semiconductor structure with a conductor on an UBM pad in accordance with some embodiments.

FIG. 8 is a flow diagram of a method of manufacturing a semiconductor structure in accordance with some embodiments.

FIG. 8A is a schematic view of a semiconductor structure with a substrate and a passivation in accordance with some embodiments.

FIG. 8B is a schematic view of a semiconductor structure with an UBM layer in accordance with some embodiments.

FIG. 8C is a schematic view of a semiconductor structure with a photoresist in accordance with some embodiments.

FIG. 8D is a schematic view of a semiconductor structure with several openings of a photoresist in accordance with some embodiments.

FIG. 8E is a schematic view of a semiconductor structure with several conductors within several openings of a photoresist in accordance with some embodiments.

FIG. 8F is a schematic view of a semiconductor structure with several conductors on UBM pads in accordance with some embodiments.

FIG. 8G is a schematic view of a semiconductor structure with a first substrate and a second substrate in accordance with some embodiments.

FIG. 8H is a schematic view of a semiconductor structure with a first substrate bonded with a second substrate in accordance with some embodiments.

### DETAILED DESCRIPTION OF THE DISCLOSURE

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A semiconductor device includes active devices, conductive trace for electrically connecting the active devices, and dielectric layers for isolating the conductive layers from each other. The dielectric layers include low dielectric constant (k), ultra low-k, extreme low-k dielectric materials or combination thereof. These low-k dielectric materials improve electrical properties of the dielectric layers and thus increase an operating efficiency of the semiconductor device. However, the low-k dielectric materials exhibit some structural deficiencies. The low-k dielectric materials tend to delaminate or develop cracks within the dielectric layers when a stress derived from various operations such as surface mounting technology (SMT) or flip chip bonding is exhibited on the low-k dielectric materials.

Further, components in the semiconductor device becomes smaller and smaller. For example, a critical dimension of an under bump metallurgy (UBM) becomes smaller. The UBM with small critical dimension induces delamination of underfill material and polymeric material disposed underneath or adjacent to the UBM. A minimization of the semiconductor device leads to a high stress on components, poor bondability between components and thus a poor reliability of the semiconductor device.

In the present disclosure, a semiconductor structure with a structural improvement is disclosed. The semiconductor structure includes a conductor disposed on an UBM pad with an undercut profile. The undercut profile of the conductor enlarges a base portion of the conductor. The base portion of the conductor is protruded from a top portion of the conductor. As an interface between the UBM pad and the conductor is increased, an effective critical dimension of the UBM pad is also increased and thus a stress on dielectric layers of the semiconductor structure would be mitigated. Therefore, delamination of dielectric layers is prevented and a reliability of the semiconductor device is improved.

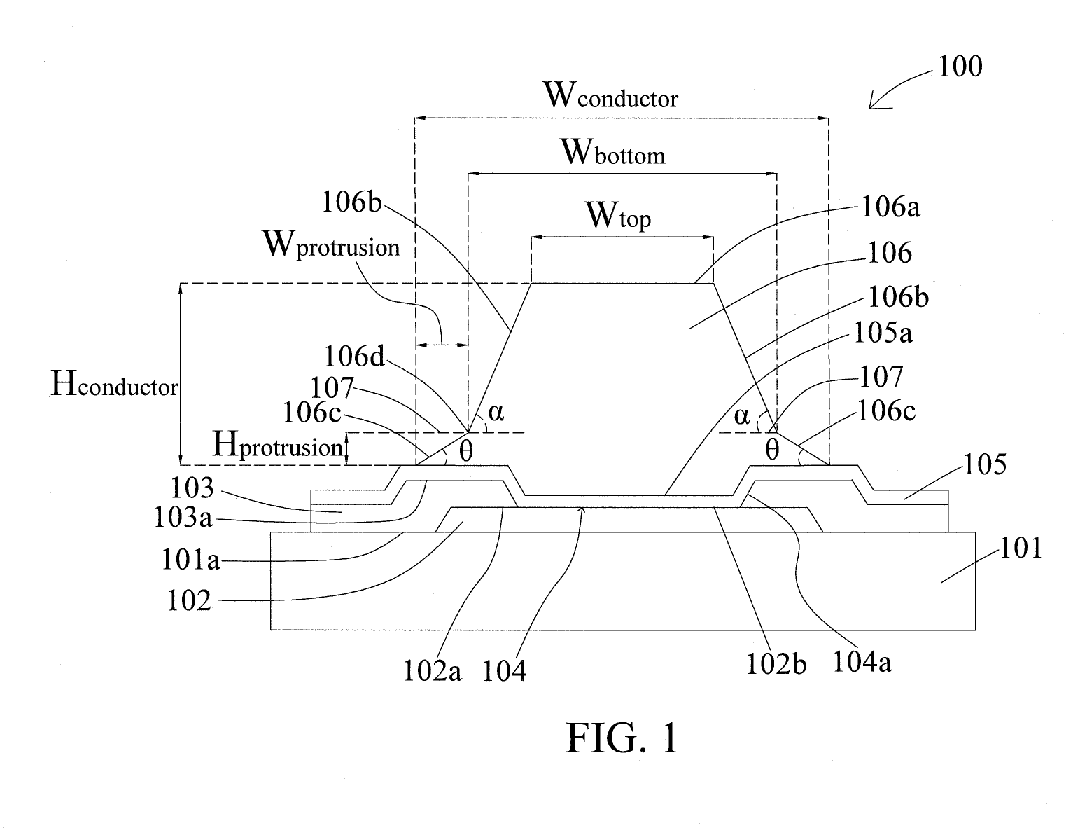

FIG. 1 is a semiconductor structure 100 in accordance with various embodiments of the present disclosure. The semiconductor structure 100 includes a substrate 101. In some embodiments, the substrate 101 includes silicon, germanium, gallium, arsenic, and combinations thereof. In some embodiments, the substrate 101 is a silicon or glass substrate. In some embodiments, the substrate 101 includes multi-layered substrates, gradient substrates, hybrid orientation substrates, any combinations thereof and/or the like. In some embodiments, the substrate 101 is in a form of silicon-on-insulator (SOI). The SOI substrate comprises a layer of a semiconductor material (e.g., silicon, germanium and/or the like) formed over an insulator layer (e.g., buried oxide, silicon oxide and/or the like).

In some embodiments, the substrate 101 is an interposer, a packaging substrate, a high density interconnect or a printed circuit board disposed with an integrated circuit die. In some embodiments, the die is a small piece including semiconductor materials such as silicon and is fabricated with a predetermined functional circuit within the die produced by photolithography operations. In some embodiments, the die is singulated from a silicon wafer by a mechanical or laser blade. In some embodiments, the die is in a quadrilateral, a rectangular or a square shape.

In some embodiments, the substrate 101 includes electrical circuitry. In some embodiments, the electrical circuitry includes several metal layers and several dielectric layers. The metal layer are interlaid with the dielectric layers. In some embodiments, the metal layer is disposed between adjacent dielectric layers to route electrical signals between electrical devices formed on or within the substrate 101. In some embodiments, the dielectric layers include low dielectric constant (low-k) materials, ultra low dielectric constant (ULK) materials or extreme low dielectric constant (ELK) materials.

In some embodiments, the electrical circuitry includes various n-type metal-oxide semiconductor (NMOS) and/or p-type metal-oxide semiconductor (PMOS) devices such as transistors, capacitors, resistors, diodes, photo-diodes, fuses and/or the like. In some embodiments, the electrical circuitry is interconnected to perform one or more functions such as memory structures, processing structures, sensors, amplifiers, power distribution, input/output circuitry and/or the like.

In some embodiments, the semiconductor structure 100 includes a conductive interconnection 102. In some embodiments, the conductive interconnection 102 electrically connects the electrical circuitry of the substrate 101 with a circuit external to the substrate 101. In some embodiments, the conductive interconnection 102 is disposed on an upper surface 101a of the substrate 101. In some embodiments, the conductive interconnection 102 is exposed from the substrate 101 for receiving a conductive structure.

In some embodiments, the conductive interconnection 102 is a conductive trace of the electrical circuitry of the substrate 101 exposed from the substrate 101. In some embodiments, the conductive interconnection 102 is a conductive pad disposed on the upper surface 101a of the substrate 101. The conductive pad is exposed from the substrate 101 for electrically connecting with a circuitry external to the substrate 101, so that the electrical circuitry internal to the substrate 101 electrically connects with the circuitry external to the substrate 101 through the conductive pad. In some embodiments, the conductive interconnection 102 includes conductive materials such as copper.

In some embodiments, the semiconductor structure 100 includes a passivation 103. In some embodiments, the passivation 103 is disposed over the substrate 101 and the conductive interconnection 102. The passivation 103 covers the upper surface 101a of the substrate 101 and a portion of the conductive interconnection 102. In some embodiments, the passivation 103 covers a periphery of a top surface 102a of the conductive interconnection 102.

In some embodiments, the passivation 103 is patterned over the substrate 101 to provide a recess 104 above the conductive interconnection 102. In some embodiments, the recess 104 is extended from a top surface 103a of the passivation 103 towards the top surface 102a of the conductive interconnection 102. In some embodiments, a bottom of the recess 104 is interfaced with an exposed portion 102b of the conductive interconnection 102. In some embodiments, the exposed portion 102b is configured for receiving a conductive structure or material.

In some embodiments, the passivation 103 includes a composite structure. In some embodiments, the passivation 103 includes dielectric materials such as spin-on glass (SOG), silicon oxide, silicon oxynitride, silicon nitride or the like. In some embodiments, the passivation 103 protects underlying layers from various environmental contaminations. In some embodiments, the passivation 103 is covered by a protective layer including polyimide material. In some embodiments, the protective layer is patterned conformal to the passivation 103 and the recess 104.

In some embodiments, an under bump metallurgy (UBM) pad 105 is disposed over the passivation 103 and contacted with the exposed portion 102b of the conductive interconnection 102. In some embodiments, the UBM pad 105 is conformal to the top surface 103a of the passivation 103, a sidewall 104a of the recess 104 and the exposed portion 102b of the conductive interconnection 102.

In some embodiments, the UBM pad 105 is a metallurgical layer or a metallurgical stack film above the passivation 103. In some embodiments, the UBM pad 105 includes metal or metal alloy. The UBM pad 105 includes copper, gold or etc. In some embodiments, the UBM pad 105 is configured for electrically connecting the electrical circuitry of the substrate 101 with a circuit external to the substrate 101. In some embodiments, a redistribution layer (RDL) is included to re-route a path of the electrical circuitry from the conductive interconnection 102 to the UBM pad 105.

In some embodiments, the semiconductor structure 100 includes a conductor 106 disposed over the UBM pad 105. In some embodiments, the conductor 106 is protruded and extended from a top surface 105a of the UBM pad 105. In some embodiments, the conductor 106 includes conductive materials such as copper, gold, nickel, aluminum or etc.

In some embodiments, the conductor 106 includes a top surface 106a. In some embodiments, the top surface 106a of the conductor 106 is in various cross-sectional shapes from a top plan view of the conductor 106. In some embodiments, the top surface 106a is in a circular, quadrilateral or polygonal shape. In some embodiments, the top surface 106a is substantially parallel to the upper surface 101a of the substrate 101. In some embodiments, the top surface 106a is configured for receiving a solder material to electrically connect with another substrate.

In some embodiments, the conductor 106 has a height H_{conductor} from the UBM pad 105 to the top surface 106a. In some embodiments, the height H_{conductor} is about 10 um to about 30 um. In some embodiments, the height H_{conductor} is greater than about 15 um.

In some embodiments, the conductor 106 includes a first sloped outer surface 106b. In some embodiments, the first sloped outer surface 106b is extended from the top surface 106a. In some embodiments, the first sloped outer surface 106b is revolved about a central axis of the conductor 106.

In some embodiments, the first sloped outer surface 106b includes a first gradient α. In some embodiments, the first sloped outer surface 106b is tapered from an end 106d of the first sloped outer surface 106b to the top surface 106a of the conductor 106 in the first gradient α. In some embodiments, the first gradient α is an angle between the first sloped outer surface 106b and a horizontal axis 107. In some embodiments, the first gradient α is substantially smaller than 90°, so that a width W_{bottom} adjacent to the bottom of the conductor 106 is substantially greater than a width Wₜₒₚ adjacent to the top surface 106a of the conductor 106. In some embodiments, the width W_{bottom} is at least about 3 um greater than the width Wₜₒₚ.

In some embodiments, the first sloped outer surface 106b is a vertical surface extending from the top surface 106a towards the UBM pad 105 in the first gradient α substantially equal to 90°, so that the width W_{bottom} is substantially same as the width Wₜₒₚ. In some embodiments, the first sloped outer surface 106b is substantially orthogonal to the top surface 106a.

In some embodiments, the conductor 106 includes a second sloped outer surface 106c. In some embodiments, the second sloped outer surface 106c is extended from the end 106d of the first sloped outer surface 106b to the UBM pad 105. In some embodiments, the second sloped outer surface 106c is revolved about the central axis of the conductor 106.

In some embodiments, the second sloped outer surface 106c includes a second gradient θ. In some embodiments, the second sloped outer surface 106c is tapered from UBM pad 105 to the end 106d of the first sloped outer surface 106c in the second gradient θ.

In some embodiments, the second gradient θ is an angle between the second sloped outer surface 106c and the UBM pad 105. In some embodiments, the second gradient θ is substantially smaller than 90°, so that a width W_{conductor} of the second sloped outer surface 106c adjacent to the UBM pad 105 is substantially greater than the width W_{bottom}, and the second sloped outer surface 106c is protruded from the first sloped outer surface 106b in a width Wₚᵣₒₜᵣᵤₛᵢₒₙ and a height Hₚᵣₒₜᵣᵤₛᵢₒₙ. In some embodiments, the width W_{conductor} is the longest width of the conductor 106. In some embodiments, the width Wₚᵣₒₜᵣᵤₛᵢₒₙ is substantially greater than or equal to 1 um. In some embodiments, the height Hₚᵣₒₜᵣᵤₛᵢₒₙ is substantially greater than or equal to 1 um.

In some embodiments as in FIG. 1A, the semiconductor structure 100′ includes a second sloped outer surface 106c with a second gradient θ of a right angle. In some embodiments, the second sloped outer surface 106c is a vertical surface extending from the UBM pad 105 in the second gradient θ substantially equal to 90°. In some embodiments, the second sloped outer surface 106c is substantially orthogonal to the UBM pad 105. In some embodiments, the second sloped outer surface 106c is protruded from the first sloped outer surface 106b in a width Wₚᵣₒₜᵣᵤₛᵢₒₙ and a height Hₚᵣₒₜᵣᵤₛᵢₒₙ. In some embodiments, the width Wₚᵣₒₜᵣᵤₛᵢₒₙ is substantially greater than or equal to 1 um. In some embodiments, the height Hₚᵣₒₜᵣᵤₛᵢₒₙ is substantially equal or greater than 1 um.

Referring back to FIG. 1, the second gradient θ is substantially different from the first gradient α. In some embodiments, the second gradient θ is substantially smaller than the first gradient α, so that the second sloped outer surface 106c is protruded from the first sloped outer surface 106b, and the width W_{conductor} of the second sloped outer surface 106c adjacent to the UBM pad 105 is substantially greater than the width W_{bottom}. In some embodiments, the width W_{conductor} is the longest width of the conductor 106.

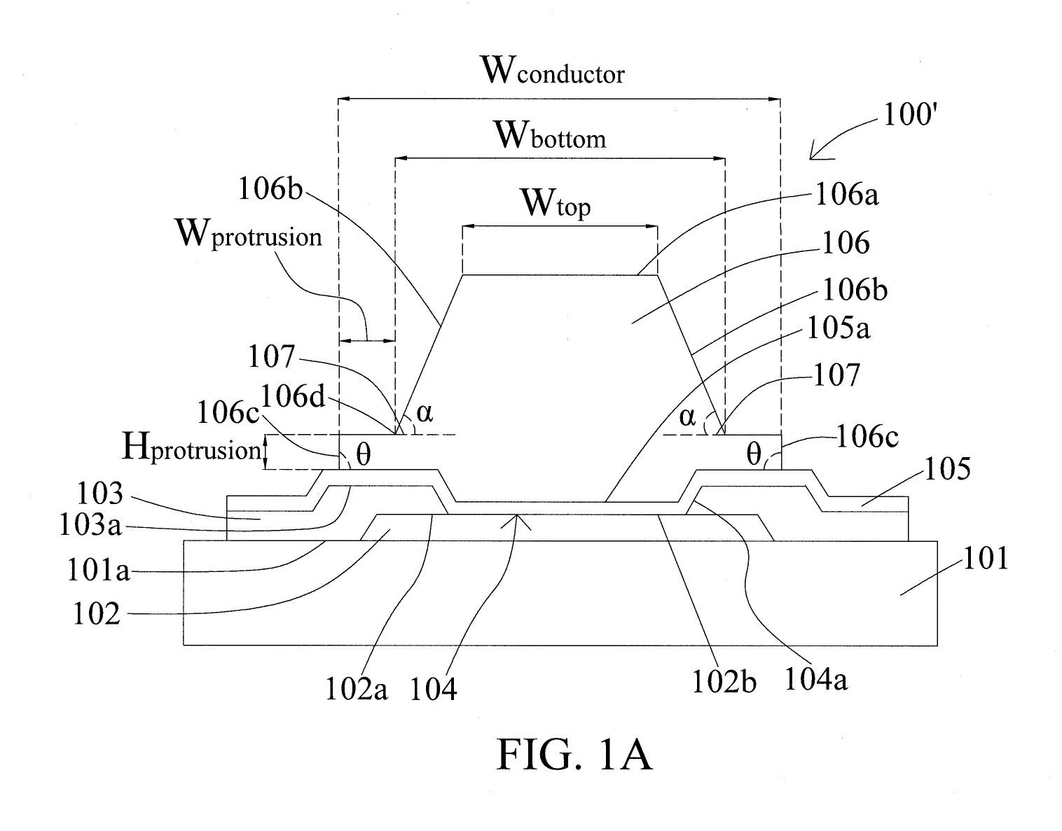

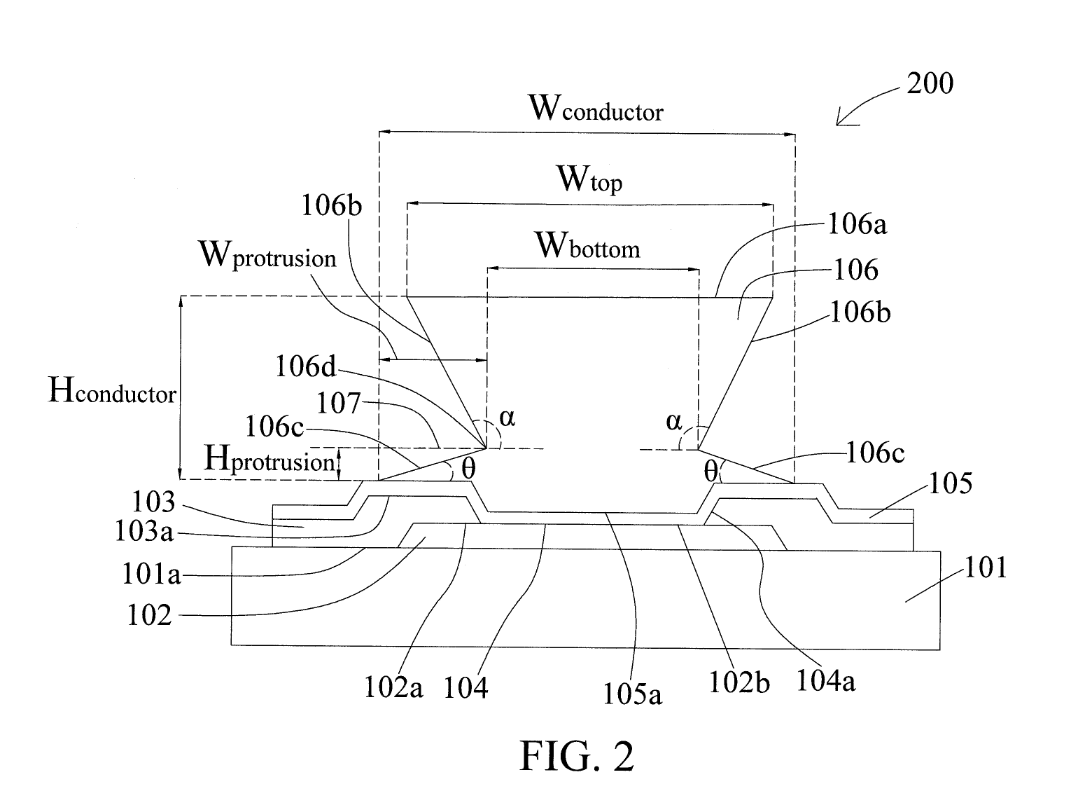

FIG. 2 is a semiconductor structure 200 in accordance with various embodiments of the present disclosure. The semiconductor structure 200 includes a substrate 101, a conductive interconnection 102, a passivation 103 and an UBM pad 105, which are in similar configurations as in FIG. 1 and FIG. 1A. In some embodiments, the semiconductor structure 200 is different from the semiconductor structure 100 of FIG. 1 in that, the first sloped outer surface 106b of the semiconductor structure 200 is in the first gradient α substantially greater than 90°, so that the width W_{bottom} adjacent to the bottom of the conductor 106 is substantially smaller than a width Wₜₒₚ adjacent to the top surface 106a of the conductor 106.

In some embodiments, the second sloped outer surface 106c is in the second gradient θ substantially smaller than 90°, so that the width W_{conductor} of the second sloped outer surface 106c adjacent to the UBM pad 105 is substantially greater than the width W_{bottom} and the width Wₜₒₚ, and the second sloped outer surface 106c is protruded from the first sloped outer surface 106b in the width Wₚᵣₒₜᵣᵤₛᵢₒₙ and the height Hₚᵣₒₜᵣᵤₛᵢₒₙ. In some embodiments, the width Wₚᵣₒₜᵣᵤₛᵢₒₙ is substantially greater than or equal to 1 um. In some embodiments, the height Hₚᵣₒₜᵣᵤₛᵢₒₙ is substantially greater than or equal to 1 um.

In some embodiments, the second gradient θ is substantially different from the first gradient α. In some embodiments, the second gradient θ is substantially smaller than the first gradient α, so that the second sloped outer surface 106c is protruded from the first sloped outer surface 106b.

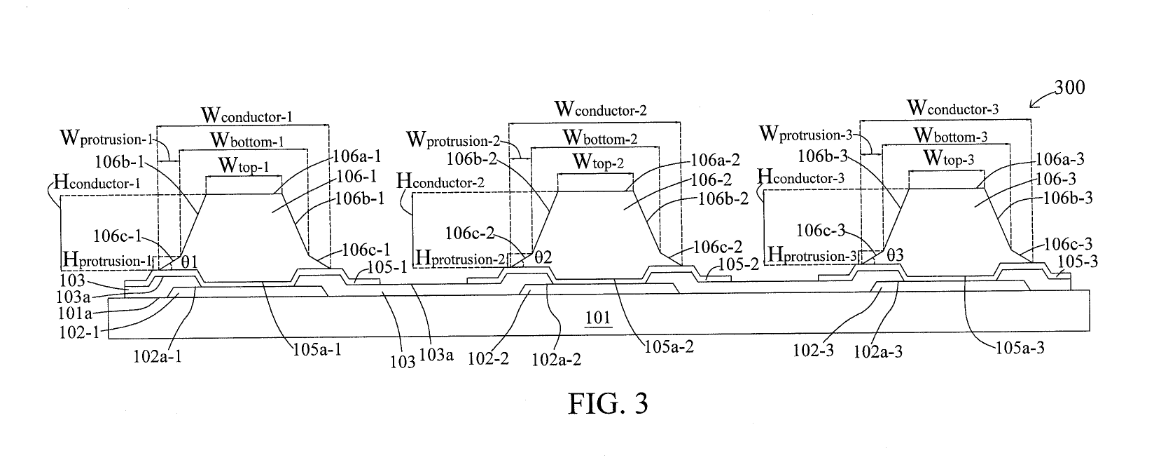

FIG. 3 is a semiconductor structure 300 in accordance with various embodiments of the present disclosure. The semiconductor structure 300 includes a substrate 101. In some embodiments, the semiconductor structure 300 further includes several conductive interconnections (102-1, 102-2, 102-3) disposed on the upper surface 101a of the substrate 101. In some embodiments, the conductive interconnections (102-1, 102-2, 102-3) are partially covered by a passivation 103, that each of the conductive interconnections (102-1, 102-2, 102-3) has an exposed portion exposed from the passivation 103.

In some embodiments, the semiconductor structure 300 includes several UBM pads (105-1, 105-2, 105-3) disposed over the passivation 103 and contacted with the exposed portions of the conductive interconnections (102-1, 102-2, 102-3) respectively. In some embodiments, the UBM pads (105-1, 105-2, 105-3) are electrically isolated from each other.

In some embodiments, the semiconductor structure 300 includes several conductors (106-1, 106-2, 106-3) disposed on the UBM pads (105-1, 105-2, 105-3) respectively. In some embodiments, the conductors (106-1, 106-2, 106-3) have similar configuration as in FIG. 1.

In some embodiments, the conductor 106-1 has a first sloped outer surface 106b-1 and a second sloped outer surface 106c-1. In some embodiments, the second sloped outer surface 106c-1 includes a second gradient θ1. In some embodiments, the second sloped outer surface 106c-1 is tapered from the UBM pad 105-1 to an end 106d of the first sloped outer surface 106c-1 in the second gradient θ.

In some embodiments, the second gradient θ1 is an angle between the second sloped outer surface 106c-1 and the UBM pad 105-1. In some embodiments, the second gradient θ1 is substantially smaller than 90°, so that the second sloped outer surface 106c-1 is protruded from the first sloped outer surface 106b-1.

In some embodiments, a width W_{conductor-1} is substantially greater than a width Wₜₒₚ₋₁ of a top surface 106a-1 and a width W_{bottom-1} adjacent to a bottom of the conductor 106-1. In some embodiments, the second sloped outer surface 106c-1 is protruded from the first sloped outer surface 106b-1 in a width Wₚᵣₒₜᵣᵤₛᵢₒₙ₋₁ and a height Hₚᵣₒₜᵣᵤₛᵢₒₙ₋₁. In some embodiments, the width Wₚᵣₒₜᵣᵤₛᵢₒₙ₋₁ is substantially greater than or equal to 1 um. In some embodiments, the height Hₚᵣₒₜᵣᵤₛᵢₒₙ₋₁ is substantially greater than or equal to 1 um.

In some embodiments, the conductor 106-2 includes a second sloped outer surface 106c-2 protruded from a first sloped outer surface 106b-2 in a second gradient θ2. In some embodiments, the second gradient θ2 is substantially same as or different from the second gradient θ1 of the conductor 106-1. In some embodiments, a width W_{conductor-2} is substantially greater than a width Wₜₒₚ₋₂ of a top surface 106a-2 and a width W_{bottom-2} adjacent to a bottom of the conductor 106-2.

In some embodiments, the second sloped outer surface 106c-2 is protruded from the first sloped outer surface 106b-2 in a width Wₚᵣₒₜᵣᵤₛᵢₒₙ₋₂ and a height Hₚᵣₒₜᵣᵤₛᵢₒₙ₋₂. In some embodiments, the width Wₚᵣₒₜᵣᵤₛᵢₒₙ₋₂ and the height Hₚᵣₒₜᵣᵤₛᵢₒₙ₋₂ are substantially same as or different from the width Wₚᵣₒₜᵣᵤₛᵢₒₙ₋₁ and the height Hₚᵣₒₜᵣᵤₛᵢₒₙ₋₁ respectively. In some embodiments, the width Wₚᵣₒₜᵣᵤₛᵢₒₙ₋₂ is substantially greater than or equal to 1 um. In some embodiments, the height Hₚᵣₒₜᵣᵤₛᵢₒₙ₋₂ is substantially greater than or equal to 1 um.

In some embodiments, the conductor 106-3 includes a second sloped outer surface 106c-3 protruded from a first sloped outer surface 106b-3 in a second gradient θ3. In some embodiments, the second gradient θ3 is substantially same as or different from the second gradient θ2 of the conductor 106-2. In some embodiments, the second gradient θ3 is substantially same as or different from the first gradient θ1 of the conductor 106-1. In some embodiments, a width W_{conductor-3} is substantially greater than a width Wₜₒₚ₋₃ of a top surface 106a-1 and a width W_{bottom-3} adjacent to a bottom of the conductor 106-3.

In some embodiments, the second sloped outer surface 106c-3 is protruded from the first sloped outer surface 106b-3 in a width Wₚᵣₒₜᵣᵤₛᵢₒₙ₋₃ and a height Hₚᵣₒₜᵣᵤₛᵢₒₙ₋₃. In some embodiments, the width Wₚᵣₒₜᵣᵤₛᵢₒₙ₋₃ and the height Hₚᵣₒₜᵣᵤₛᵢₒₙ₋₃ are substantially same as or different from the width Wₚᵣₒₜᵣᵤₛᵢₒₙ₋₁ and the height Hₚᵣₒₜᵣᵤₛᵢₒₙ₋₁ respectively. In some embodiments, the width Wₚᵣₒₜᵣᵤₛᵢₒₙ₋₃ and the height Hₚᵣₒₜᵣᵤₛᵢₒₙ₋₃ are substantially same as or different from the width Wₚᵣₒₜᵣᵤₛᵢₒₙ₋₂ and the height Hₚᵣₒₜᵣᵤₛᵢₒₙ₋₂ respectively. In some embodiments, the width Wₚᵣₒₜᵣᵤₛᵢₒₙ₋₃ is substantially greater than or equal to 1 um. In some embodiments, the height Hₚᵣₒₜᵣᵤₛᵢₒₙ₋₃ is substantially greater than or equal to 1 um.

In some embodiments, the width W_{conductor-1} of the conductor 106-1, the width W_{conductor-2} of the conductor 106-2 and the width W_{conductor-3} of the conductor 106-3 are substantially same as or different from each other. In some embodiments, a height H_{conductor-1} of the conductor 106-1, a height H_{conductor-2} of the conductor 106-2 and a height H_{conductor-3} of the conductor 106-3 are substantially same as each other. In some embodiments, the height H_{conductor-1} the height H_{conductor-2} and the height H_{conductor-3} of the conductor 106-3 are greater than about 15 um respectively.

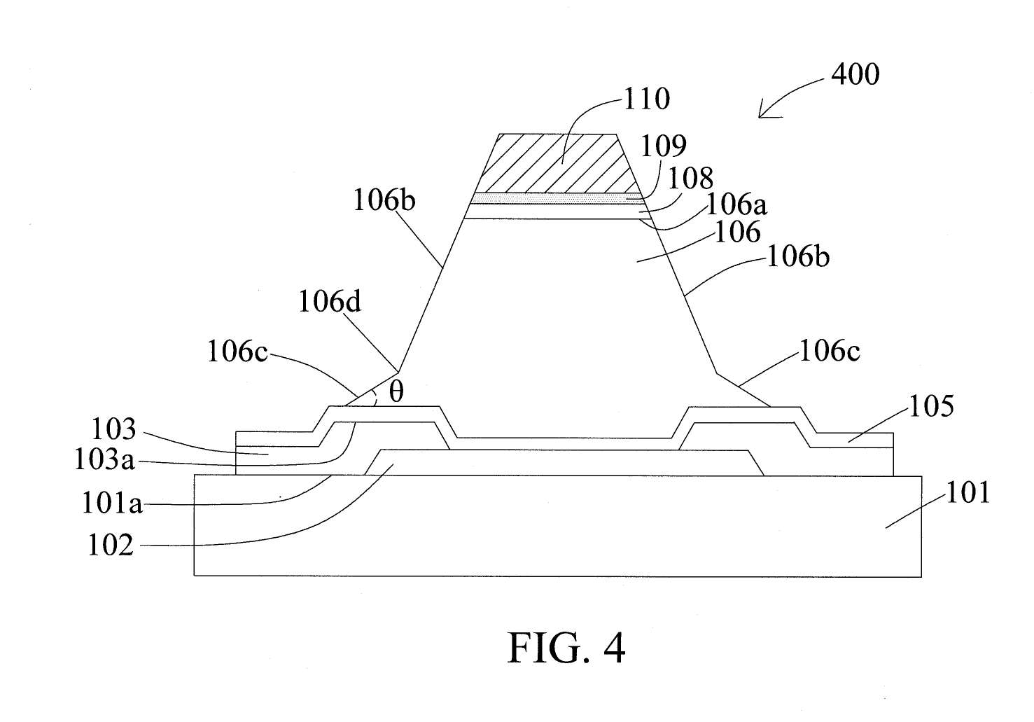

FIG. 4 is a semiconductor structure 400 in accordance with various embodiments of the present disclosure. The semiconductor structure 400 includes a substrate 101, a conductive interconnection 102, a passivation 103, an UBM pad 105 and a conductor 106 which are in similar configurations as in FIG. 1. In some embodiments, a conductive layer 108 is disposed on a top surface 106a of the conductor 106. In some embodiments, the conductive layer 108 includes gold, silver, platinum or combinations thereof.

In some embodiments, an inter-metallic compound (IMC) layer 109 is disposed on the conductive layer 108. In some embodiments, the IMC layer 109 includes metal such as copper and solder material such as tin or lead.

In some embodiments, a solder materiel 110 is disposed on the IMC layer 109. In some embodiments, the solder material 110 includes tin. Lead, a high lead material, a tin based solder, a lead free solder, a tin-silver solder, a tin-silver-copper solder or other suitable conductive material. In some embodiments, the solder material 110 is configured for bonding the conductor 106 with another substrate and thus electrically connecting the electrical circuitry of the substrate 101 with a circuitry of another substrate.

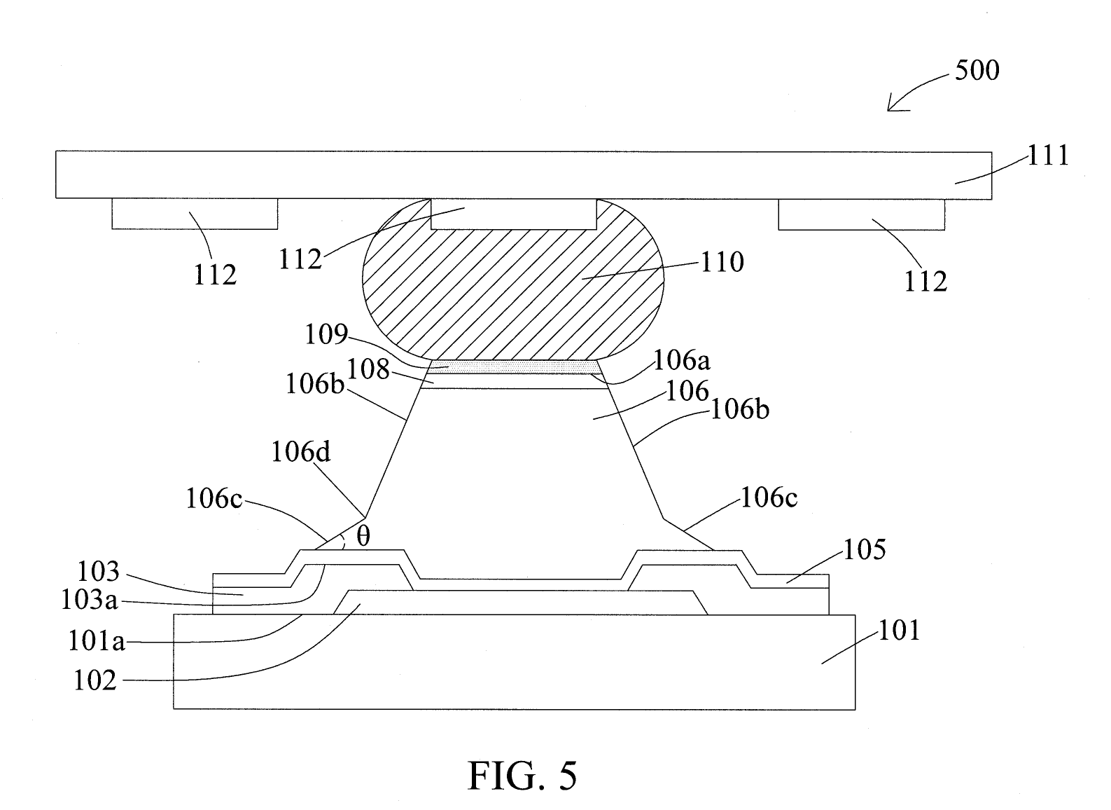

FIG. 5 is a semiconductor structure 500 in accordance with various embodiments of the present disclosure. The semiconductor structure 500 includes a first substrate 101. The first substrate 101 has similar configuration as the substrate 101 in FIG. 1. In some embodiments, the semiconductor structure 500 further includes a conductive interconnection 102, a passivation 103, an UBM pad 105, a conductor 106, a conductive layer 108 and an IMC 109 which are in similar configurations as in FIG. 1 or FIG. 4.

In some embodiments, the semiconductor structure 500 includes a second substrate 111. In some embodiments, the second substrate 111 is an organic substrate, a PCB, a ceramic substrate, an interposer, a packaging substrate, a high density interconnect, or the like. In some embodiments, the second substrate 111 includes silicon, germanium, gallium, arsenic, and combinations thereof.

In some embodiments, the second substrate 111 includes several conductive interconnection structures 112 disposed on the second substrate 111. In some embodiments, the conductive interconnection structures 112 are exposed from the second substrate 111. In some embodiments, the conductive interconnection structures 112 are conductive traces, conductive pads, a portion of a redistribution layer (RDL) or the like.

In some embodiments, the conductive interconnection structures 112 are configured for receiving conductive connectors or conductive materials to join a circuitry of the second substrate 111 with a circuitry of another substrate. In some embodiments, the conductive interconnection structures 112 includes copper, tungsten, aluminum, silver, combinations thereof, or the like.

In some embodiments, the second substrate 111 is bonded with the first substrate 101 by a solder material 110. In some embodiments, the solder material 110 is disposed between one of the conductive interconnection structures 112 and the conductor 106. In some embodiments, the solder material 110 is disposed between one of the conductive interconnection structures 112 and the IMC layer 109 or the conductive layer 108. In some embodiments, the circuitry of the first substrate 101 and the circuitry of the second substrate 111 are electrically connected through the solder material 110.

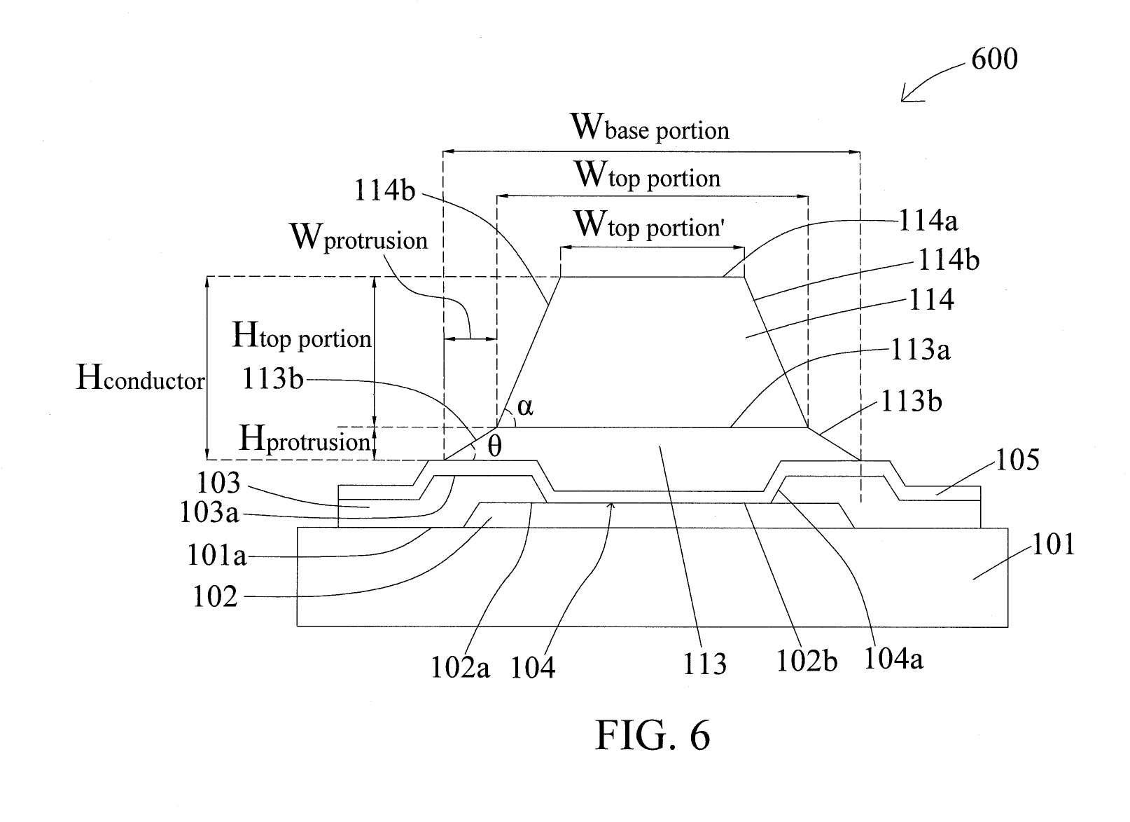

FIG. 6 is an embodiment of a semiconductor structure 600 in accordance with various embodiments of the present disclosure. The semiconductor structure 600 includes a substrate 101, a conductive interconnection 102, a passivation 103 and an UBM pad 105, which are in similar configurations as in FIG. 1.

In some embodiments, the semiconductor structure 600 includes a conductive base portion 113. In some embodiments, the conductive base portion 113 is disposed on the UBM pad 105. In some embodiments, the conductive base portion 113 includes conductive materials such as copper, gold, nickel, aluminum or etc.

In some embodiments, the conductive base portion 113 includes a first top surface 113a and a first outer surface 113b extended from the UBM pad 105 to the first top surface 113a. In some embodiments, the first outer surface 113b is tapered from the UBM pad 105 to the first top surface 113a in a first angle θ. In some embodiments, the first angle θ is an angle between the first outer surface 113b and the UBM pad 105. In some embodiments, the first angle of the conductive base portion 113 is substantially smaller than 90°.

In some embodiments, the semiconductor structure 600 includes a conductive top portion 114. In some embodiments, the conductive top portion 114 is disposed on the first top surface 113a. In some embodiments, the conductive top portion 114 is in a conical shape. In some embodiments, the conductive top portion 114 includes conductive materials such as copper, gold, nickel, aluminum or etc. In some embodiments, the conductive top portion 114 include same conductive material as the conductive base portion 113. In some embodiments, the conductive top portion 114 is integral with the conductive base portion 113.

In some embodiments, the conductive top portion 114 includes a second top surface 114a and a second outer surface 114b extended from the first top surface 113a to the second top surface 114a. In some embodiments, the second top surface 114a is configured for receiving a solder material and thus for bonding the substrate 101 with another substrate. In some embodiments, the second outer surface 114b is tapered from the second top surface 11a to the first top surface 113a in a second angle α. In some embodiments, the second angle α is an angle between the second outer surface 114b and the first top surface 113a of the conductive base portion 113. In some embodiments, the second angle α of the conductive top portion 114 is substantially smaller than 90°.

In some embodiments, the conductive base portion 113 is protruded from the conductive top portion 114 in a width Wₚᵣₒₜᵣᵤₛᵢₒₙ of greater than or equal to about 1 um. In some embodiments, the conductive base portion 113 has a height Hₚᵣₒₜᵣᵤₛᵢₒₙ of greater than or equal to about 1 um. In some embodiments, a ratio of the height Hₚᵣₒₜᵣᵤₛᵢₒₙ of the conductive base portion 113 to a height H_{top portion} of the conductive top portion 114 is about 1:3 to about 1:20. In some embodiments, the ratio of the height Hₚᵣₒₜᵣᵤₛᵢₒₙ to the height H_{top portion} is about 1:5. In some embodiments, a total height H_{conductor} of the conductive base portion 113 and the conductive top portion 114 is greater than about 15 um.

In some embodiments, the conductive base portion 113 has a width W_{base portion} which is a length of an interface between the conductive base portion 113 and the UBM pad 105. In some embodiments, the conductive top portion 114 has a longest length W_{top portion} parallel to the second top surface 114a. In some embodiments, the width W_{base portion} is substantially greater than the longest length W_{top portion}. In some embodiments, the width W_{base portion} is about 2 um greater than the longest length W_{top portion}. In some embodiments, a difference between the longest length W_{top portion} of the conductive top portion 114 parallel to the second top surface 114a and a shortest length W_{top portion′} of the conductive top portion 114 parallel to the second top surface 114a is greater than about 3 um.

In the present disclosure, a method of manufacturing a semiconductor structure is also disclosed. In some embodiments, a semiconductor structure is formed by a method 700. The method 700 includes a number of operations and the description and illustration are not deemed as a limitation as the sequence of the operations.

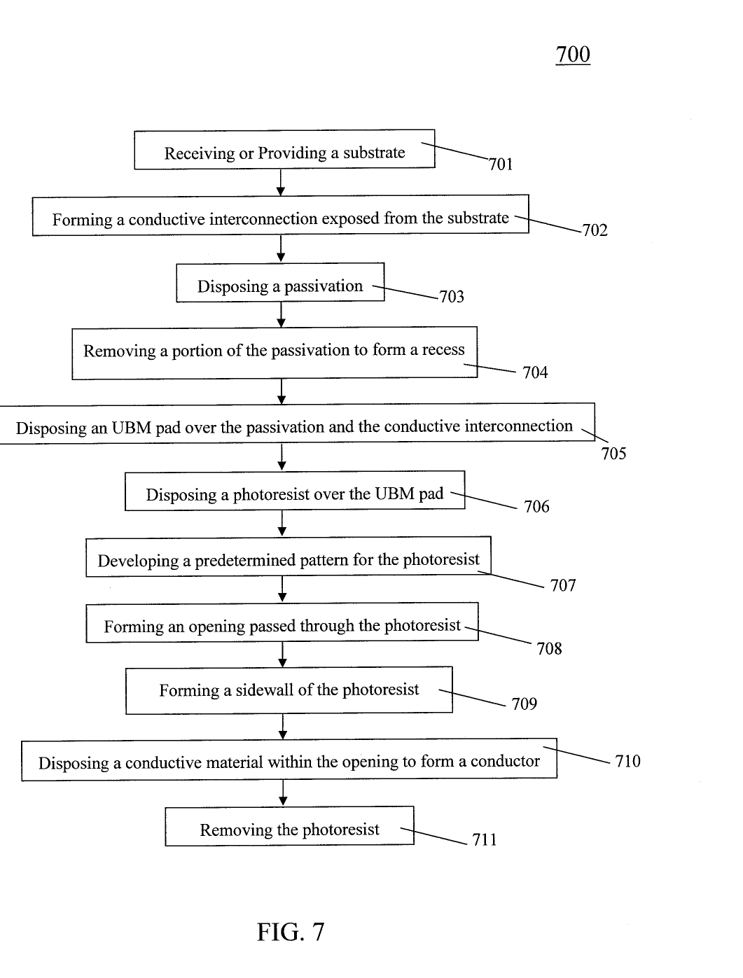

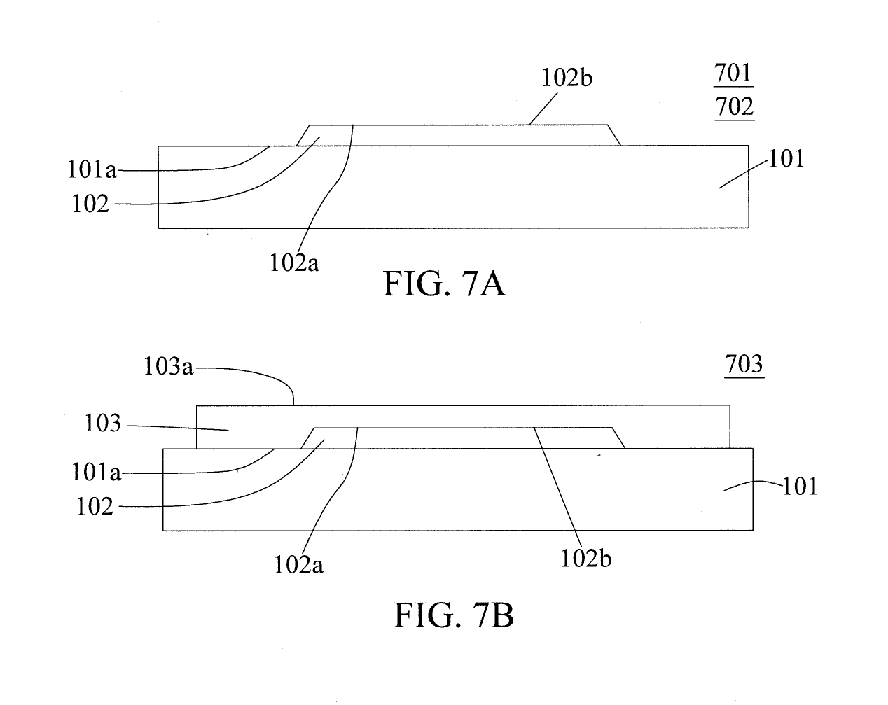

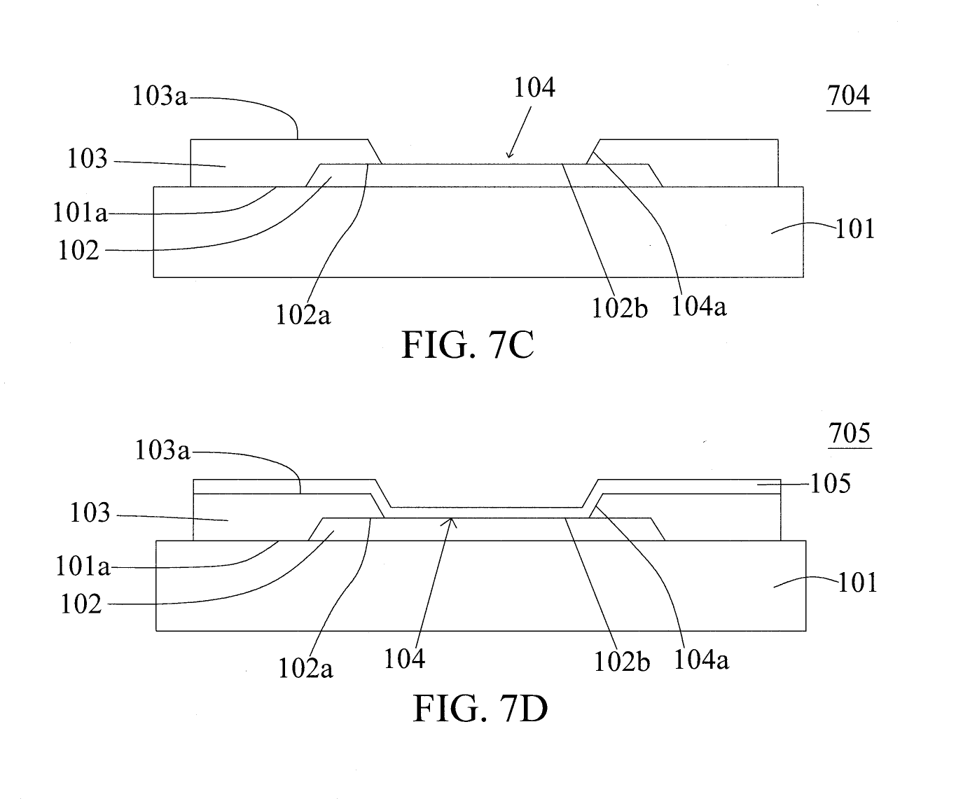

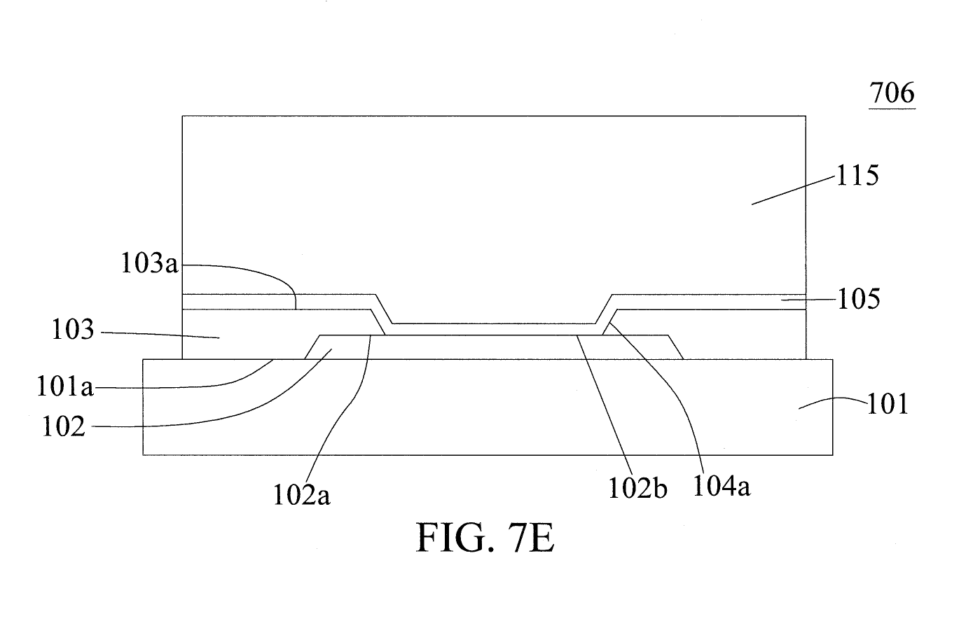

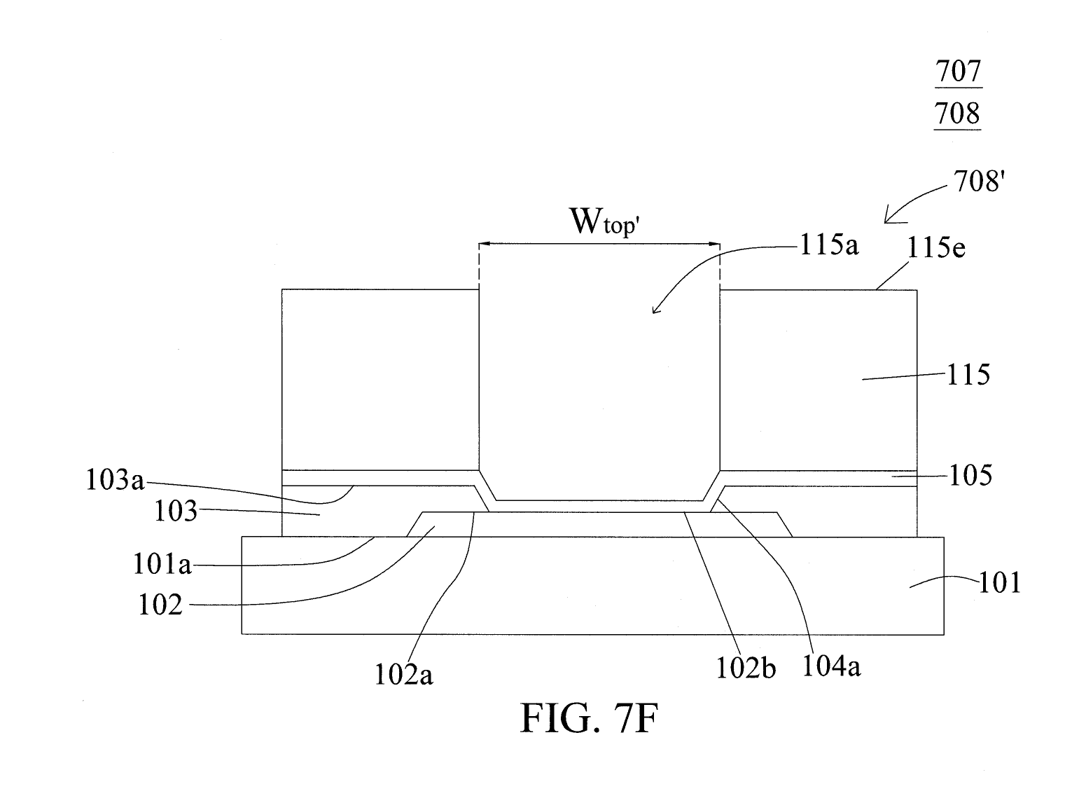

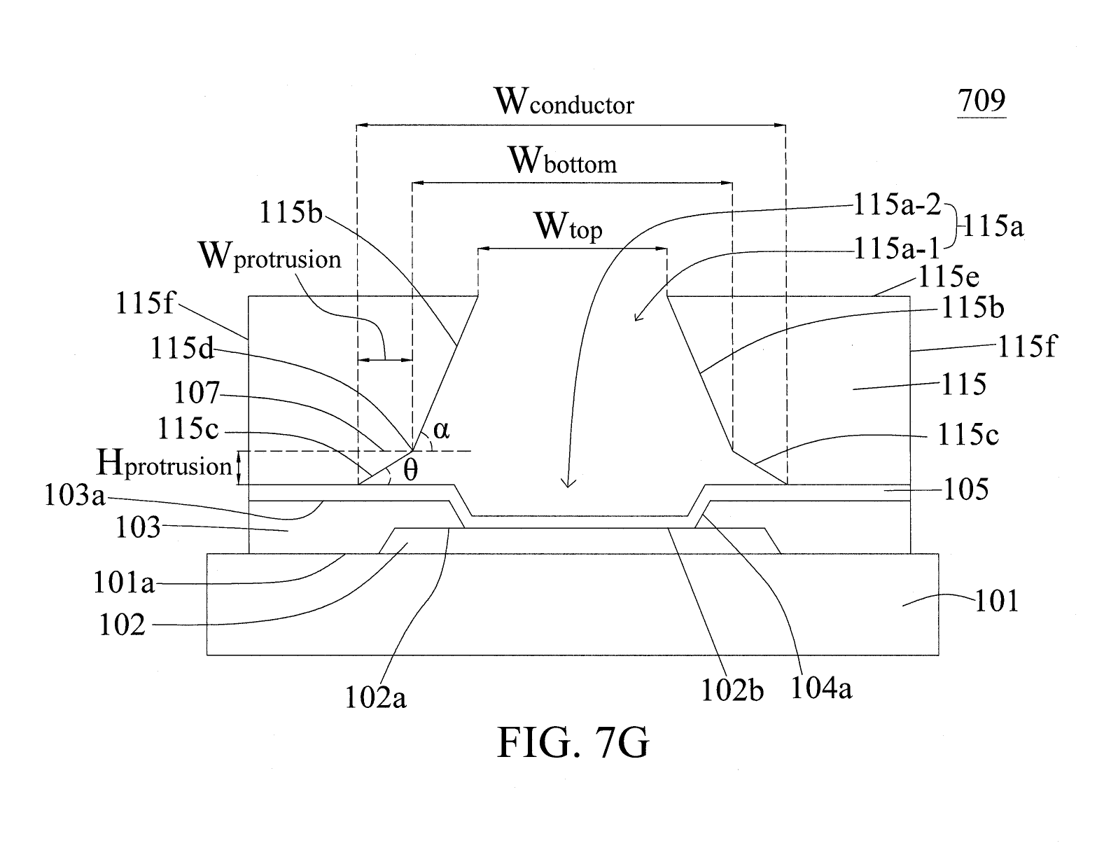

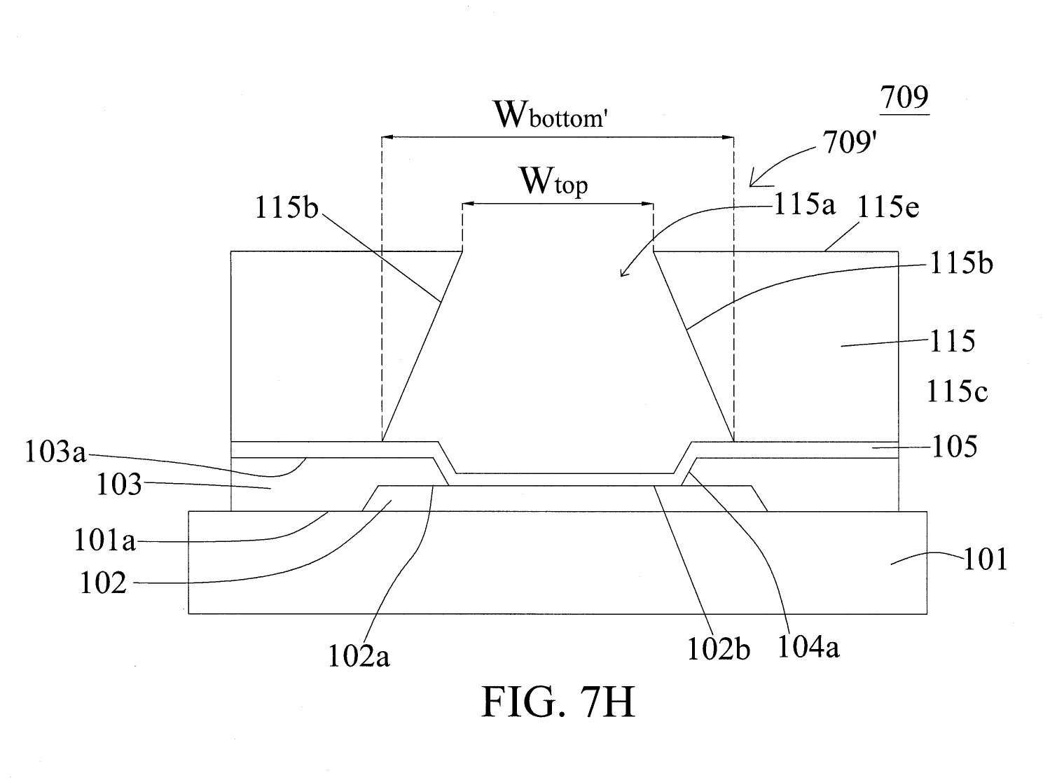

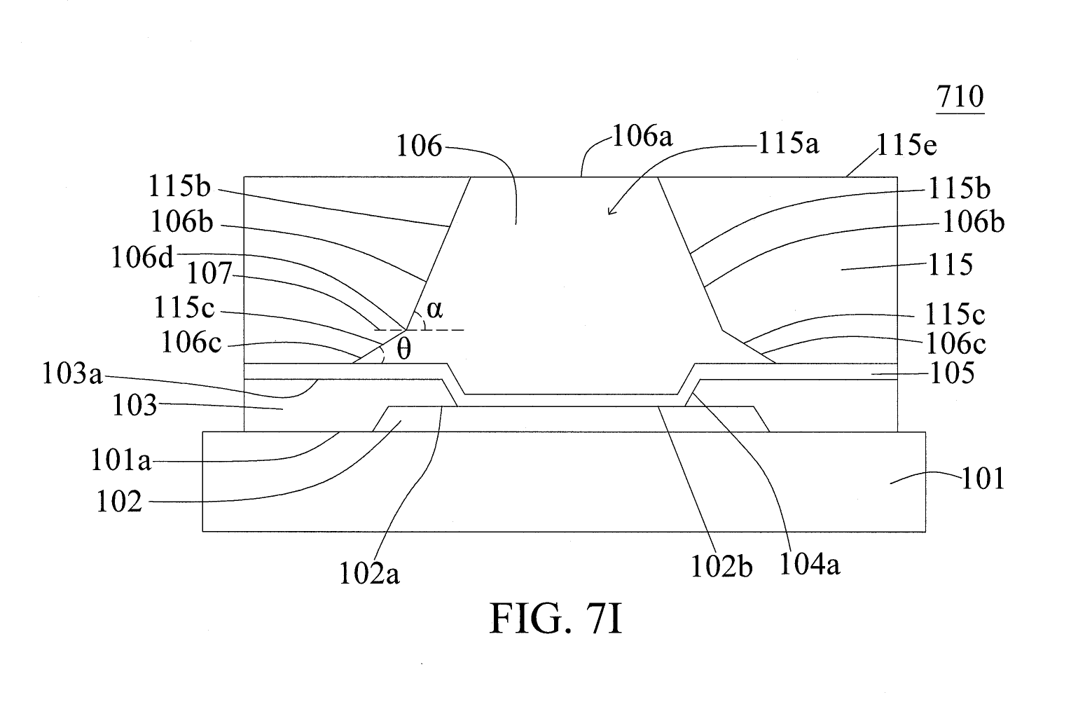

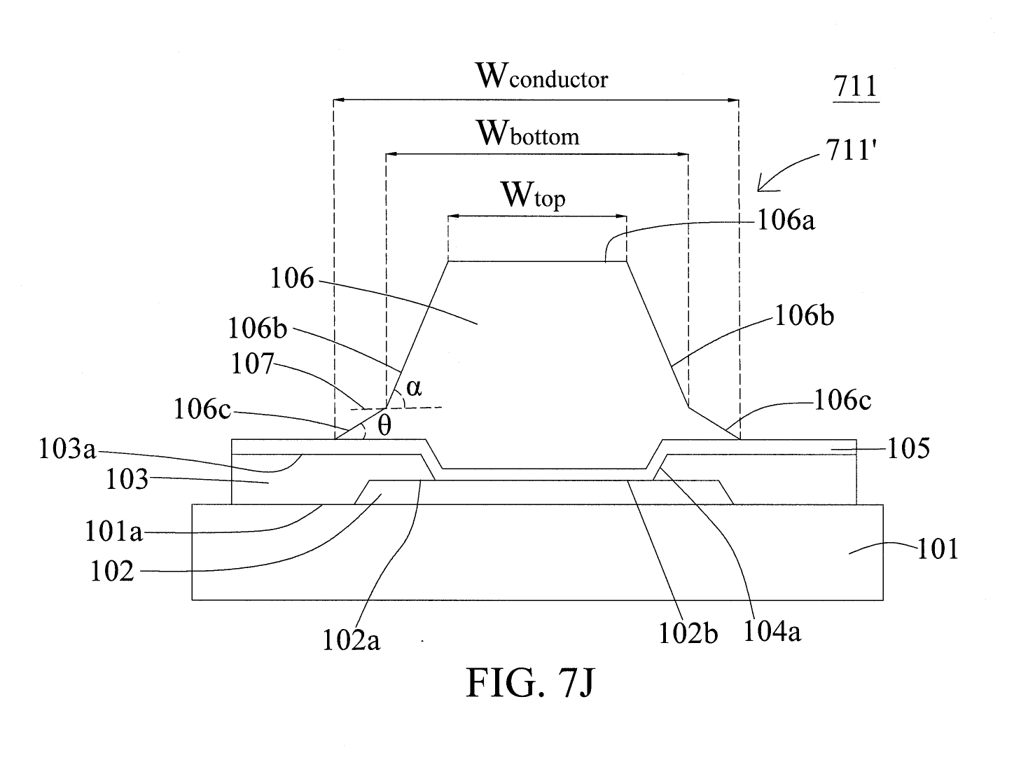

FIG. 7 is a flowchart of a method 700 of manufacturing a semiconductor structure in accordance with various embodiments of the present disclosure. In some embodiments, the method 700 manufactures the semiconductor structure similar to the semiconductor structure 100 as in FIG. 1. The method 700 includes a number of operations (701, 702, 703, 704, 705, 706, 707, 708, 709, 710 and 711).

In operation 701, a substrate 101 is received or provided as in FIG. 7A. In some embodiments, the substrate 101 has similar configuration as in FIG. 1. In some embodiments, the substrate 101 includes several ELK dielectric layers.

In operation 702, a conductive interconnection 102 is formed on or within the substrate 101 as in FIG. 7A. In some embodiments, the conductive interconnection 102 is formed and exposed from the substrate 101. The conductive interconnection 102 is exposed from an upper surface 101a of the substrate 101. In some embodiments, the conductive interconnection 102 has similar configuration as in FIG. 1. In some embodiments, the conductive interconnection 102 is electrically connected with a circuitry of the substrate 102.

In some embodiments, the conductive interconnection 102 is a conductive pad or a conductive trace. In some embodiments, the conductive interconnection 102 is formed by a damascene or dual damascene operation including removing an excess conductive material such as copper or gold by a chemical mechanical polishing (CMP) and overfilling the conductive material into an opening.

In operation 703, a passivation 103 is disposed over the conductive interconnection 102 and the substrate 101 as in FIG. 7B. In some embodiments, the passivation 103 covers the conductive interconnection 102 and the upper surface 101a of the substrate 101 to protect the conductive interconnection 102 and the circuitry of the substrate 101. In some embodiments, the passivation 103 has similar configuration as in FIG. 1. In some embodiments, the passivation 103 is formed by chemical vapor disposition (CVD), physical vapor disposition (PVD) or the like.

In operation 704, a portion of the passivation 103 is removed to form a recess 104 as in FIG. 7C. In some embodiments, the passivation 103 is patterned to provide the recess 104 above a top surface 102a of the conductive interconnection 102. In some embodiments, the recess 104 is formed by etching or any other suitable operations. In some embodiments, the recess 104 has similar configuration as in FIG. 1.

In operation 705, an UBM pad 105 is disposed over the passivation 103 and the conductive interconnection 102 as in FIG. 7D. In some embodiments, a conductive material such as copper is disposed over the passivation 103 and an exposed portion 102b of the conductive interconnection 102 to form the UBM pad 105. In some embodiments, the UBM pad 105 is contacted and thus electrically connected with the conductive interconnection 102. In some embodiments, the UBM pad 105 has similar configuration as in FIG. 1. In some embodiments, the UBM pad 105 is conformal to a sidewall 104a of the recess 104 and a top surface 103a of the passivation 103. In some embodiments, the UBM pad 105 is disposed by various method such as sputtering or electroplating operation.

In operation 706, a photoresist 115 is disposed over the UBM pad 105 as in FIG. 7E. In some embodiments, the photoresist 115 is evenly disposed on the UBM pad 105 by spin coating operation. In some embodiments, the photoresist 115 is temporarily coated on the UBM pad 105. In some embodiments, the photoresist 115 is pre-baked on a hotplate after the spin coating operation.

In some embodiments, the photoresist 115 is a light sensitive material with chemical properties depending on an exposure of light. In some embodiments, the photoresist 115 is sensitive to an electromagnetic radiation such as an ultra violet (UV) light, that the chemical properties of the photoresist 115 is changed upon exposure to the UV light.

In some embodiments, the photoresist 115 is a positive photoresist. The positive photoresist exposed to the UV light is dissolvable by a developer solution, while the positive photoresist unexposed to the UV light is not dissolvable by the developer solution. In some embodiments, the photoresist 115 is a negative photoresist. The negative photoresist exposed to the UV light is not dissolvable by a developer solution, while the negative photoresist unexposed to the UV light is dissolvable by the developer solution.

In operation 707, a predetermined pattern is developed for the photoresist 115 as in FIG. 7F. In some embodiments, a photomask with a predetermined pattern is disposed above the photoresist 115. In some embodiments, the photomask includes silica, glass or etc. In some embodiments, the photomask has the predetermined pattern corresponding to a position of an opening 115a to be formed within the photoresist 115 and above the UBM pad 105. In some embodiments, the photomask includes a light passing portion and a light blocking portion, such that an electromagnetic radiation such as UV light can pass through the light passing portion but cannot pass through the light blocking portion. In some embodiments, the predetermined pattern of the photomask is reproduced to the photoresist 115 after exposing the photoresist 115 to the electromagnetic radiation. In some embodiments, a portion of the photoresist 115 above the UBM pad 105 is exposed to the electromagnetic radiation, such that the portion of the photoresist 115 is dissolvable by a developer solution.

In operation 708, an opening 115a passed through the photoresist 115 is formed as in FIG. 7F. In some embodiments, the portion of the photoresist 115 above the UBM pad 105 and exposed to the electromagnetic radiation is dissolved by the developer solution to form the opening 115a. In some embodiments, the photomask 107 is removed after forming the opening 115a.

In operation 709, a sidewall (115b, 115c) of the photoresist 115 is formed as in FIG. 7G. In some embodiments, the sidewall (115b, 115c) includes a first sidewall 115b and a second sidewall 115c. In some embodiments, the first sidewall 115b is tapered from an end 115d of the first sidewall 115b towards a top surface 115e of the photoresist 115, as such a width Wₜₒₚ of the opening 115a adjacent to the top surface 115e is smaller than a width W_{bottom} of the opening 115a adjacent to the UBM pad 105. In some embodiments, the width Wₜₒₚ is substantially smaller than the width W_{top′} of FIG. 7F. In some embodiments, the second sidewall 115c is tapered from the UBM pad 105 to the end 115d of the first sidewall 115b.

In some embodiments, the first sidewall 115b is inclined in a first gradient α, and the second sidewall 115c is inclined in a second gradient θ. In some embodiments, the first gradient α is an angle between the first sidewall 115b and a horizontal axis 107, and the second gradient θ is an angle between the second sidewall 115c and the UBM pad 105.

In some embodiments, the first gradient α is substantially greater than the second gradient θ. In some embodiments, the first gradient α and the second gradient θ are substantially smaller than 90°. In some embodiments, the second sidewall 115c is shrunken from the first sidewall 115b in a length Wₚᵣₒₜᵣᵤₛᵢₒₙ and a height Hₚᵣₒₜᵣᵤₛᵢₒₙ of greater than or equal to about 1 um respectively.

In some embodiments, the opening 115a includes a first opening 115a-1 and a second opening 115a-2. In some embodiments, the first opening 115a-1 is extended from the top surface 115e of the photoresist 115, and the second opening 115a-2 is extended from the UBM pad to the first opening 115a-1. In some embodiments, a width W_{conductor} of the second opening 115a-2 is substantially greater than the width W_{bottom} of the first opening 115a-1.

In some embodiments, the sidewall (115b, 115c) is formed by rinse and drying operation. As the photoresist 115 includes cross-linker with a high cross link density of about 25%, there is a tendency to form the sidewall (115b, 115c) including the first sidewall 115b and the second sidewall 115c. In some embodiments, the photoresist 115 includes R-M-OOH, where R represents photo active compound (PAC), M represents monomer or cross linker, and OOH represents oxygen and hydrogen respectively.

In some embodiments, a semiconductor structure 708′ of FIG. 7F is spun at a predetermined acceleration exceeding an adhesion between the photoresist 115 and the UBM pad 105, so that the photoresist 115 adjacent to the UBM pad 105 is shrunken towards an outer sidewall 115f to form the second sidewall 115c tapered from the UBM pad 105 towards the end 115d as in FIG. 7G. In some embodiments, the semiconductor structure 708′ of FIG. 7F is spun at the predetermined acceleration of about 6000 revolutions per minute (rpm).

In some embodiments, the first sidewall 115b is formed as in FIG. 7H and then the second sidewall 115c is formed as in FIG. 7G. In some embodiments, the first sidewall 115b is tapered from the UBM pad 105 towards the top surface 115e of the photoresist 115, as such the width Wₜₒₚ of the opening 115a adjacent to the top surface 115e is smaller than a width W_{bottom}′ of the opening 115a adjacent to the UBM pad 105.

In some embodiments, the first sidewall 115b is formed by any suitable operations such as swelling, image reversal, multiple exposures using different mask, or the like. In some embodiments, a portion of the photoresist 115 adjacent to the top surface 115e is more hydrophilic than a portion of the photoresist 115 adjacent to the UBM pad 105, and thus the width Wₜₒₚ of the portion of the photoresist 115 adjacent to the top surface 115e is narrower than the width W_{bottom}′ of the portion of the photoresist 115 adjacent to the UBM pad 105. As such, the first sidewall 115b is formed. In some embodiments, the width Wₜₒₚ′ of the opening 115a adjacent to the top surface 115e in the operation 708 as in FIG. 7F is greater than the width Wₜₒₚ in FIG. 7G.

After formation of the first sidewall 115b, the second sidewall 115c is formed. In some embodiments, the second sidewall 115c is formed because the photoresist 115 has a high cross link density and thus has a tendency to shrink from the opening 115a towards the outer sidewall 115f of the photoresist 115.

In some embodiments, the second sidewall 115c is formed by rinse and drying operation. In some embodiments, the semiconductor structure 709′ of FIG. 7H is spun at a predetermined acceleration exceeding an adhesion between the photoresist 115 and the UBM pad 105, so that the photoresist 115 adjacent to the UBM pad 105 is shrunken towards the outer sidewall 115f to form the second sidewall 115c tapered from the UBM pad 105 towards to end 115d as in FIG. 7G. In some embodiments, the semiconductor structure 709′ of FIG. 7H is spun at the predetermined acceleration of about 6000 revolutions per minute (rpm). In some embodiments, the first sidewall 115b is inclined in the first gradient α, and the second sidewall 115c is inclined in the second gradient θ.

In operation 710, a conductive material is disposed within the opening 115a to form a conductor 106 as in FIG. 7I. In some embodiments, the conductive material such as copper is disposed by electroplating, electroless plating or etc to form the conductor 106 on the UBM pad 105.

In some embodiments, the conductor 106 includes a top surface 106a, a first sloped outer surface 106b and a second sloped outer surface 106c. In some embodiments, the first sloped outer surface 106b is extended from the top surface 106a, and the second sloped outer surface 106b is extended from an end 106d of the first sloped outer surface 106b to the UBM pad 105. In some embodiments, the first sloped outer surface 106b is inclined in the first gradient α, and the second sloped outer surface 106c is inclined in the second gradient θ. In some embodiments, the second gradient θ is substantially smaller than the first gradient α.

In some embodiments, the first sloped outer surface 106b is conformal to the first sidewall 115b of the opening 115a of the photoresist 115, and the second sloped outer surface 106c is conformal to the second sidewall 115c of the opening 115a of the photoresist 115. In some embodiments, the first sloped outer surface 106b is interfaced with the first sidewall 115b, and the second sloped outer surface 106c is interfaced with the second sidewall 115c.

In operation 711, the photoresist 115 is removed from the UBM pad 105 as in FIG. 7J. In some embodiments, the photoresist 115 is removed by any suitable method such as stripping, plasma ashing, dry etching, or the like. After removal of the photoresist 115, the conductor 106 with the first sloped outer surface 106b and the second sloped outer surface 106c is disposed on the UBM pad 105. In some embodiments, the conductor 106 has similar configuration as in FIG. 1.

In some embodiments, the second sloped outer surface 106c is protruded greater than or equal to about 1 um from the first sloped outer surface 106b. In some embodiments, a width W_{conductor} of the second sloped outer surface 106c is substantially greater than the width Wₜₒₚ or the width W_{bottom} of the first sloped outer surface 106b. As the second sloped outer surface 106c is protruded from the first sloped outer surface 106b, a stress on the dielectric layers on the substrate 101 is decreased and thus a reliability of the semiconductor structure 711′ is increased. In some embodiments, if the second sloped outer surface 106c is about 2 um protruded from the first sloped outer surface 106b, the stress is decreased of about 8%.

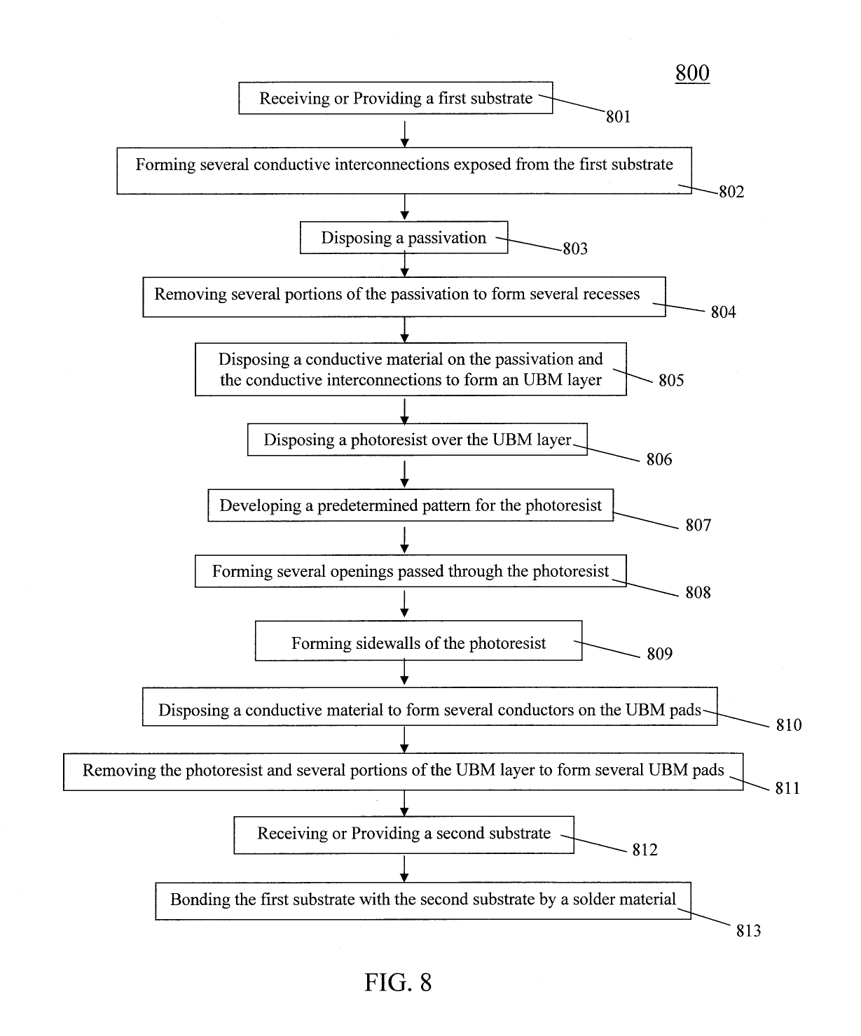

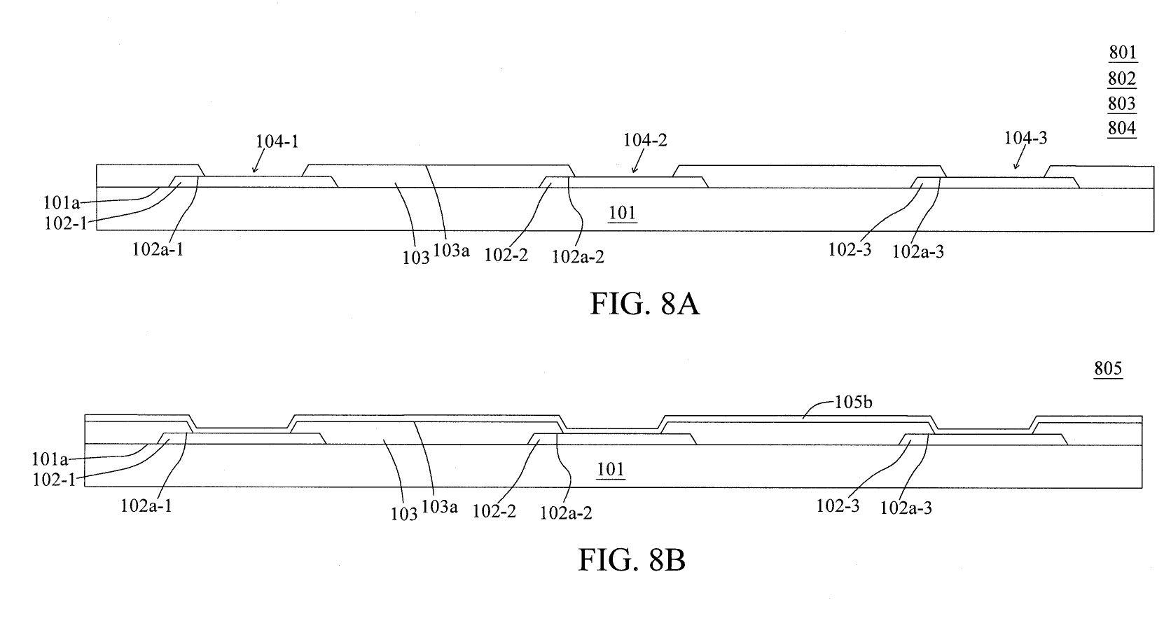

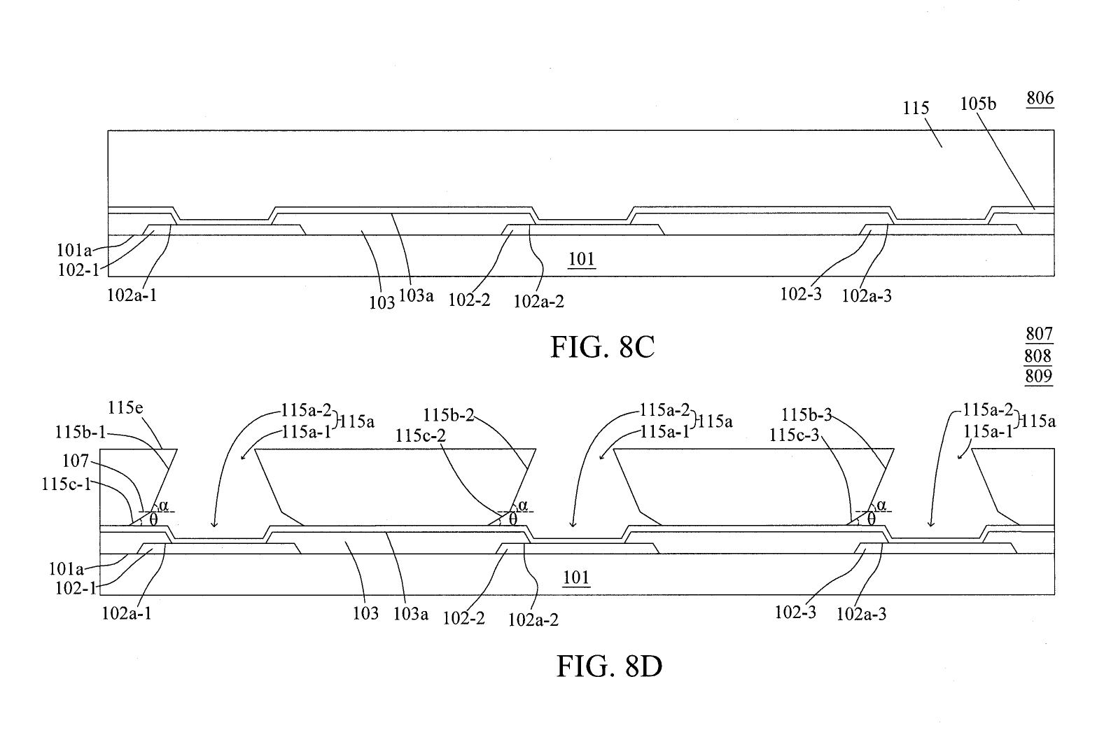

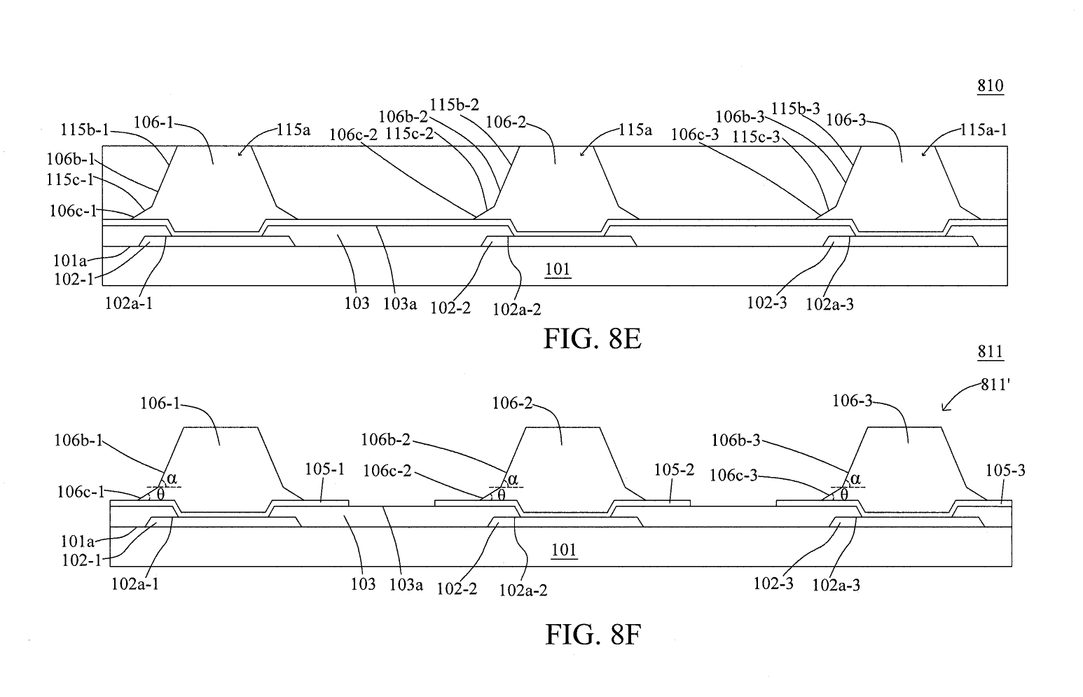

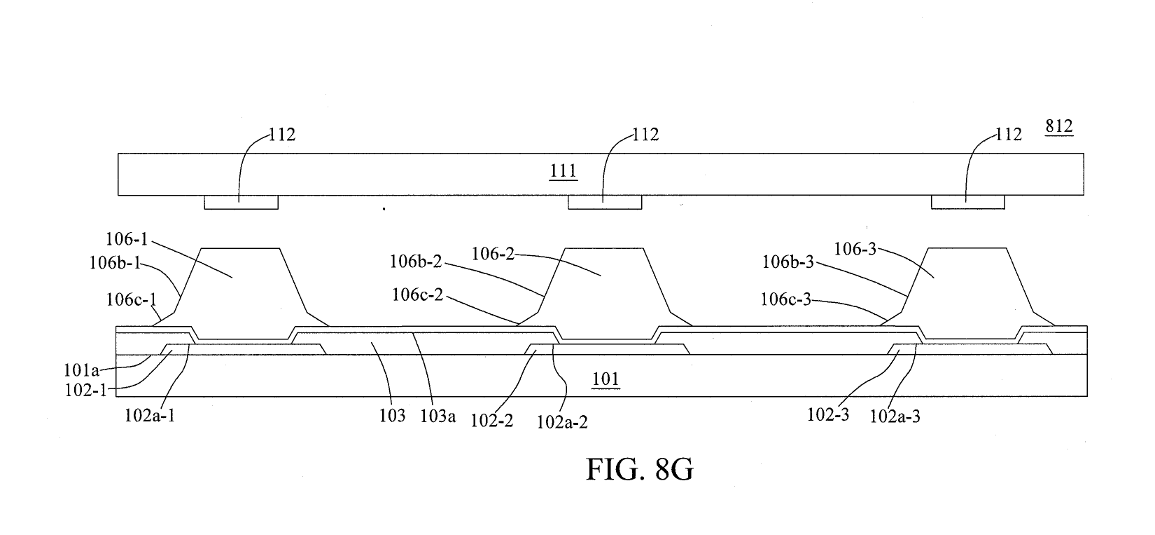

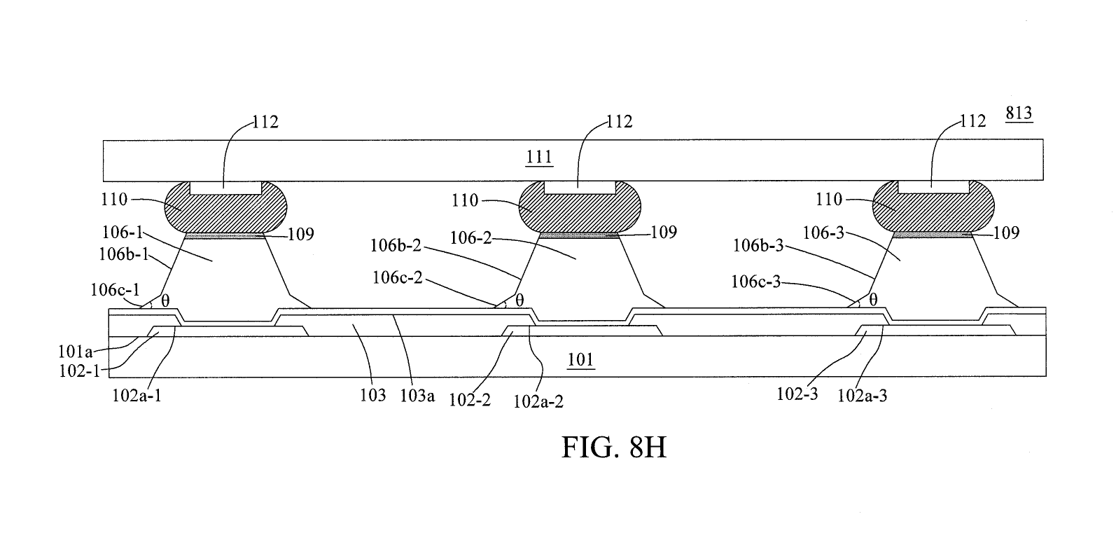

FIG. 8 is a flowchart of a method 800 of manufacturing a semiconductor structure in accordance with various embodiments of the present disclosure. In some embodiments, the method 800 manufactures the semiconductor structure similar to the semiconductor structure 500 as in FIG. 5. The method 800 includes a number of operations (801, 802, 803, 804, 805, 806, 807, 808, 809, 810, 811, 812 and 813).

In operation 801, a first substrate 101 is received or provided as in FIG. 8A. In some embodiments, the first substrate 101 has similar configuration as the substrate 101 in FIG. 1. In some embodiments, the operation 801 is similar to the operation 701.

In operation 802, several conductive interconnections (102-1, 102-2, 102-3) are disposed on an upper surface 101a of the first substrate 101 as in FIG. 8A. In some embodiments, the conductive interconnections (102-1, 102-2, 102-3) are exposed from the first substrate 101. In some embodiments, each of the conductive interconnections (102-1, 102-2, 102-3) has similar configuration as the conductive interconnection 102 in FIG. 1. In some embodiments, the operation 802 is similar to the operation 702.

In operation 803, a passivation 103 is disposed over the conductive interconnections (102-1, 102-2, 102-3) and the first substrate 101 as in FIG. 8A. In some embodiments, the operation 803 is similar to the operation 703.

In operation 804, several portions of the passivation 103 are removed to form several recesses (104-1, 104-2, 104-3) as in FIG. 8A. In some embodiments, the portions of the passivation 103 above the conductive interconnections (102-1, 102-2, 102-3) are removed to form the recesses (104-1, 104-2, 104-3) respectively. In some embodiments, each of the recesses (104-1, 104-2, 104-3) has similar configuration as the recess 104 in FIG. 1. In some embodiments, the operation 804 is similar to the operation 704.

In operation 805, a conductive material is disposed on the passivation 103 and exposed portions of the conductive interconnections (102-1, 102-2, 102-3) to form an UBM layer 105b as in FIG. 8B. In some embodiments, several portions of the UBM layer 105b are contacted with the conductive interconnections (102-1, 102-2, 102-3). In some embodiments, the UBM payer 105b has similar configuration as the UBM pad in FIG. 1. In some embodiments, the operation 805 is similar to the operation 705.

In operation 806, a photoresist 115 is disposed over the UBM layer 105b as in FIG. 8C. In some embodiments, the operation 806 is similar to the operation 706.

In operation 807, a predetermined pattern is developed for the photoresist 115 by a photomask. In some embodiments, the photomask with the predetermined pattern is disposed above the photoresist 115. In some embodiments, the photomask has the predetermined pattern corresponding to positions of openings 115a to be formed above each of the conductive interconnections (102-1, 102-2, 102-3). In some embodiments, the operation 807 is similar to the operation 707.

In operation 808, several openings 115a passed through the photoresist 115 are formed as in FIG. 8D. In some embodiments, several portions of photoresist 115 above the conductive interconnections (102-1, 102-2, 102-3) are dissolved by a developer solution to form the openings 115a. In some embodiments, the operation 808 is similar to the operation 708.

In operation 809, several sidewalls (115b-1, 115b-2, 115b-3, 115c-1, 115c-2, 115c-3) of the photoresist 115 including several first sidewalls (115b-1, 115b-2, 115b-3) and several second sidewalls (115c-1, 115c-2, 115c-3) are formed as in FIG. 8D. In some embodiments, the photoresist 115 has a high cross link density, such that the sidewalls (115b-1, 115b-2, 115b-3, 115c-1, 115c-2, 115c-3) are formed by rinse and drying at a predetermined acceleration. In some embodiments, the first sidewalls (115b-1, 115b-2, 115b-3) are respectively tapered from the second sidewalls (115c-1, 115c-2, 115c-3) towards a top surface 115e of the photoresist 115, and the second sidewalls (115c-1, 115c-2, 115c-3) are respectively tapered from the UBM layer 105b to the first sidewalls (115b-1, 115b-2, 115b-3). In some embodiments, the operation 809 is similar to the operation 709 as in FIG. 7G.

In some embodiments, the first sidewalls (115b-1, 115b-2, 115b-3) are formed, and then the second sidewalls (115c-1, 115c-2, 115c-3) are formed as in FIG. 8D. In some embodiments, the first sidewalls (115b-1, 115b-2, 115b-3) similar to the first sidewall 115b of FIG. 7H are formed, and then the second sidewalls (115c-1, 115c-2, 115c-3) similar to the second sidewall 115c of FIG. 7G are formed.

In some embodiments, the first sidewalls (115b-1, 115b-2, 115b-3) are formed by swelling, and then the second sidewalls (115c-1, 115c-2, 115c-3) are formed by rinse and drying. In some embodiments, the photoresist 115 adjacent to the UBM pad 105 is shrunken towards the outer sidewall 115f by spinning at a predetermined acceleration to form the second sidewalls (115c-1, 115c-2, 115c-3) tapered from the UBM pad 105 towards the end 115d of the first sidewalls (115b-1, 115b-2, 115b-3). In some embodiments, each of the openings 115a of the photoresist 115 includes a first opening 115a-1 and a second opening 115a-2 which have similar configuration as in FIG. 7G.

In operation 810, a conductive material is disposed within the openings 115a to form several conductors (106-1, 106-2, 106-3) on the UBM layer 105b as in FIG. 8E. In some embodiments, several first sloped outer surfaces (106b-1, 106b-2, 106b-3) of the conductors (106-1, 106-2, 106-3) are conformal to the first sidewalls (115b-1, 115b-2, 115b-3) of the photoresist 115. In some embodiments, several second sloped outer surfaces (106c-1, 106c-2, 106c-3) of the conductors (106-1, 106-2, 106-3) are conformal to the second sidewalls (115c-1, 115c-2, 115c-3) of the photoresist 115. In some embodiments, the operation 811 is similar to the operation 711.

In operation 811, the photoresist 115 is removed from the UBM layer 105b as in FIG. 8F. In some embodiments, the photoresist 115 is removed by any suitable method such as stripping, plasma ashing, dry etching, or the like. In some embodiments, an semiconductor structure 811′ has similar configuration as the semiconductor structure 300 in FIG. 3. In some embodiments, each of the conductors (106-1, 106-2, 106-3) has similar configuration as the conductor 106 in FIG. 1.

Furthermore, several portions of the UBM layer 105b are removed to form several UBM pads (105-1, 105-2, 105-3) by any suitable methods such as etching. In some embodiments, the portions of the UBM layer 105b between the adjacent conductors (106-1, 106-2, 106-3) are removed, such that the UBM pads (105-1, 105-2, 105-3) are electrically isolated from each other. In some embodiments, the conductors (106-1, 106-2, 106-3) are supported and protruded from the UBM pads (105-1, 105-2, 105-3) respectively. In some embodiments, each of the UBM pads (105-1, 105-2, 105-3) has similar configuration as the UBM pad 105 in FIG. 1.

In operation 812, a second substrate 111 is received or provided as in FIG. 8G. In some embodiments, several conductive interconnection structures 112 are disposed on the second substrate 111. In some embodiments, the second substrate 111 has similar configuration as in FIG. 5.

In operation 813, the first substrate 101 is bonded with the second substrate 111 by a solder material 110 as in FIG. 8H. In some embodiments, the conductive interconnection structures 112 are bonded with the corresponding conductors (106-1, 106-2, 106-3) respectively by the solder material 110. In some embodiments, the solder material 110 electrically connects the circuitry of the first substrate 101 with a circuitry of the second substrate 111 through the conductors (106-1, 106-2, 106-3) and the conductive interconnection structures 112. In some embodiments, an IMC layer 109 is formed between the solder material 110 and the conductors (106-1, 106-2, 106-3) when the conductors (106-1, 106-2, 106-3) is bonded with the conductive interconnection structures 112. In some embodiments, the first substrate 101 is bonded with the second substrate 111 to form a semiconductor package such as a flip chip package.

In the present disclosure, a semiconductor structure includes a conductor disposed on an UBM pad with an undercut profile. A base portion of the conductor is protruded from a top portion of the conductor, so that the base portion of the conductor is enlarged and a stress on dielectric layers of the semiconductor structure would be minimized. Therefore, delamination of dielectric layers is prevented.

In some embodiments, a semiconductor structure includes a substrate, a conductive interconnection exposed from the substrate, a passivation covering the substrate and a portion of the conductive interconnection, an under bump metallurgy (UBM) pad disposed over the passivation and contacted with an exposed portion of the conductive interconnection, and a conductor disposed over the UBM pad, wherein the conductor includes a top surface, a first sloped outer surface extended from the top surface and including a first gradient, and a second sloped outer surface extended from an end of the first sloped outer surface to the UBM pad and including a second gradient substantially smaller than the first gradient.

In some embodiments, the second sloped outer surface is greater than or equal to about 1 um protruded from the first sloped outer surface. In some embodiments, the first gradient or the second gradient is substantially smaller than 90°. In some embodiments, the conductor includes copper. In some embodiments, the conductor has a height of greater than about 15 um. In some embodiments, the top surface is configured for receiving a solder material.

In some embodiments, a semiconductor structure includes a substrate, a conductive interconnection exposed from the substrate, a passivation covering the substrate and a portion of the conductive interconnection, an under bump metallurgy (UBM) pad disposed over the passivation and contacted with an exposed portion of the conductive interconnection, a conductive base portion disposed on the UBM pad and including a first top surface and a first outer surface extended from the UBM pad to the first top surface, and a conductive top portion disposed on the first top surface of the conductive base portion and including a second top surface and a second outer surface extended from the first top surface to the second top surface, wherein a length of an interface between the conductive base portion and the UBM pad is substantially greater than a longest length of the conductive top portion parallel to the second top surface, and a first angle between the first outer surface and the UBM pad is substantially smaller than a second angle between the second outer surface and the conductive base portion.

In some embodiments, the conductive top portion is integral with the conductive base portion. In some embodiments, the conductive top portion and the conductive base portion include same conductive material. In some embodiments, the conductive top portion and the conductive base portion includes copper. In some embodiments, the length of the interface between the conductive base portion and the UBM pad is about 2 um greater than the longest length of the conductive top portion parallel to the second top surface. In some embodiments, the conductive top portion is in a conical shape. In some embodiments, the first angle of the conductive base portion or the second angle of the conductive base portion is substantially smaller than 90°. In some embodiments, a ratio of a height of the conductive base portion to a height of the conductive top portion is about 1:5. In some embodiments, a height of the conductive base portion is greater than or equal to about 1 um. In some embodiments, a difference between the longest length of the conductive top portion parallel to the second top surface and a shortest length of the conductive top portion parallel to the second top surface is greater than about 3 um.

In some embodiments, a method of manufacturing a semiconductor structure includes forming a conductive interconnection exposed from a substrate, disposing a patterned passivation over the conductive interconnection and the substrate, disposing an UBM pad over the passivation and on the conductive interconnection, disposing a photoresist over the UBM, forming an opening passed through the photoresist, disposing a conductive material within the opening to form a conductor, wherein the conductor includes a top surface, a first sloped outer surface extended from the top surface and including a first gradient, and a second sloped outer surface extended from an end of the first sloped outer surface to the UBM pad and including a second gradient substantially smaller than the first gradient.

In some embodiments, the first sloped outer surface is conformal to a first sidewall of the opening and the second sloped outer surface is conformal to a second sidewall of the opening. In some embodiments, the opening of the photoresist includes a first opening and a second opening extended from the UBM pad to the first opening, and a length of the second opening is substantially greater than a length of the first opening. In some embodiments, the opening of the photoresist includes a first sidewall inclined in the first gradient and a second sidewall inclined in the second gradient.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate;
a conductive interconnection exposed from the substrate;
a passivation covering the substrate and a portion of the conductive interconnection;
an under bump metallurgy (UBM) pad disposed over the passivation and contacted with an exposed portion of the conductive interconnection; and
a conductor disposed over the UBM pad,
wherein the conductor includes a top surface, a first sloped outer surface extended from the top surface and including a first gradient, and a second sloped outer surface extended from an end of the first sloped outer surface to the UBM pad and including a second gradient substantially smaller than the first gradient.

2. The semiconductor structure of claim 1, wherein the second sloped outer surface is substantially greater than or equal to about 1 um protruded from the first sloped outer surface.

3. The semiconductor structure of claim 1, wherein the first gradient or the second gradient is substantially smaller than 90°.

4. The semiconductor structure of claim 1, wherein the conductor includes copper.

5. The semiconductor structure of claim 1, wherein the conductor has a height of greater than about 15 um.

6. The semiconductor structure of claim 1, wherein the top surface is configured for receiving a solder material.

7. A semiconductor structure, comprising:
a substrate;
a conductive interconnection exposed from the substrate;
a passivation covering the substrate and a portion of the conductive interconnection;
an under bump metallurgy (UBM) pad disposed over the passivation and contacted with an exposed portion of the conductive interconnection;
a conductive base portion disposed on the UBM pad and including a first top surface and a first outer surface extended from the UBM pad to the first top surface; and
a conductive top portion disposed on the first top surface of the conductive base portion and including a second top surface and a second outer surface extended from the first top surface to the second top surface,
wherein a length of an interface between the conductive base portion and the UBM pad is substantially greater than a longest length of the conductive top portion parallel to the second top surface, and a first angle between the first outer surface and the UBM pad is substantially smaller than a second angle between the second outer surface and the conductive base portion.

8. The semiconductor structure of claim 7, wherein the conductive top portion is integral with the conductive base portion.

9. The semiconductor structure of claim 7, wherein the conductive top portion and the conductive base portion include same conductive material.

10. The semiconductor structure of claim 7, wherein the conductive top portion and the conductive base portion includes copper.

11. The semiconductor structure of claim 7, wherein the length of the interface between the conductive base portion and the UBM pad is about 2 um greater than the longest length of the conductive top portion parallel to the second top surface.

12. The semiconductor structure of claim 7, wherein the conductive top portion is in a conical shape.

13. The semiconductor structure of claim 7, wherein the first angle of the conductive base portion or the second angle of the conductive base portion is substantially smaller than 90°.

14. The semiconductor structure of claim 7, wherein a ratio of a height of the conductive base portion to a height of the conductive top portion is about 1:5.

15. The semiconductor structure of claim 7, wherein a height of the conductive base portion is substantially greater than or equal to about 1 um.

16. The semiconductor structure of claim 7, wherein a difference between the longest length of the conductive top portion parallel to the second top surface and a shortest length of the conductive top portion parallel to the second top surface is greater than about 3 um.

17. A method of manufacturing a semiconductor structure, comprising:
forming a conductive interconnection exposed from a substrate;
disposing a patterned passivation over the conductive interconnection and the substrate;
disposing an UBM pad over the passivation and on the conductive interconnection;
disposing a photoresist over the UBM pad;
forming an opening passed through the photoresist; and
disposing a conductive material within the opening to form a conductor,
wherein the conductor includes a top surface, a first sloped outer surface extended from the top surface and including a first gradient, and a second sloped outer surface extended from an end of the first sloped outer surface to the UBM pad and including a second gradient substantially smaller than the first gradient.

18. The method of claim 17, wherein the first sloped outer surface is conformal to a first sidewall of the opening and the second sloped outer surface is conformal to a second sidewall of the opening.

19. The method of claim 17, wherein the opening of the photoresist includes a first opening and a second opening extended from the UBM pad to the first opening, and a length of the second opening is substantially greater than a length of the first opening.

20. The method of claim 17, wherein the opening of the photoresist includes a first sidewall inclined in the first gradient and a second sidewall inclined in the second gradient.
